(19) United States
(12) Patent Application Publication
(10) Pub. No.: US 2024/0297285 A1
(43) Pub. Date: Sep. 5, 2024

(54) DISPLAY DEVICE AND METHOD OF MANUFACTURING THE SAME

(71) Applicant: Samsung Display Co., LTD., Yongin-si (KR)

(72) Inventors: Myeong Su SO, Yongin-si (KR); Ji Eun PARK, Yongin-si (KR)

(21) Appl. No.: 18/440,774

(22) Filed: Feb. 13, 2024

(30) Foreign Application Priority Data
Mar. 2, 2023 (KR) 10-2023-0028018

(51) Int. Cl. H01L 33/62; H01L 25/00; H01L 25/075; H01L 33/30

(52) U.S. Cl. CPC H01L 33/62; H01L 25/0753; H01L 25/50; H01L 33/30

(57) ABSTRACT

A display device may include: a substrate; a light emitting element on the substrate; a first pixel electrode on one area of the light emitting element and is electrically connected to the light emitting element; and a second pixel electrode on an other area of the light emitting element and is electrically connected to the light emitting element. The light emitting element may include: a first semiconductor layer, an active layer, and second and third semiconductor layers sequentially arranged along a first direction; and an insulative film covering outer surfaces of the first semiconductor layer, the active layer, and the second and third semiconductor layers. An opening exposing at least one side surface of the second semiconductor layer to the outside while penetrating the insulative film. The second pixel electrode may be in contact with the second semiconductor layer.

### CROSS-REFERENCE TO RELATED APPLICATION

The present application claims priority to and the benefit of Korean Patent Application No. 10-2023-0028018 filed on Mar. 2, 2023, in the Korean Intellectual Property Office, the entire disclosure of which is incorporated by reference herein.

### BACKGROUND

### 1. Field

The present disclosure generally relates to a display device and a method of manufacturing the same.

### 2. Description of Related Art

Recently, as interest in information displays is increased, research and development of display devices have been continuously conducted.

### SUMMARY

Embodiments of the present disclosure provide a display device and a method of manufacturing the same, which can reduce a contact resistance between a light emitting element and a pixels electrode, which is generated by the shape of a fracture surface of the light emitting element or an electrical short circuit between the light emitting element and the pixel electrode, which occurs according to an arrangement direction of the light emitting element.

In accordance with one or more embodiments of the present disclosure, there is provided a display device including: a substrate; a light emitting element on the substrate; a first pixel electrode on one area of the light emitting element, the first pixel electrode being electrically connected to the light emitting element; and a second pixel electrode on an other area of the light emitting element, the second pixel electrode being electrically connected to the light emitting element, wherein the light emitting element includes: a first semiconductor layer, an active layer, a second semiconductor layer, and a third semiconductor layer sequentially arranged along a first direction; and an insulative film covering outer surfaces of the first semiconductor layer, the active layer, the second semiconductor layer, and the third semiconductor layer, wherein an opening exposing at least one side surface of the second semiconductor layer to the outside while penetrating the insulative film, and wherein the second pixel electrode is in contact with the second semiconductor layer.

In a plan view, the opening of the insulative film may not overlap with the active layer and the third semiconductor layer.

The opening of the insulative film may be closer to the third semiconductor layer than to the active layer.

The opening of the insulative film may be closer to the active layer than to the third semiconductor layer.

The first semiconductor layer may be a semiconductor layer doped with a p-type dopant, the second semiconductor layer may be a semiconductor layer doped with an n-type dopant, and the third semiconductor layer may be a semiconductor layer that is not doped.

The light emitting element may include a first end portion and a second end portion opposite the first end portion. The first semiconductor layer of the light emitting element may be adjacent to the first end portion, and the third semiconductor layer of the light emitting element may be adjacent to the second end portion. The light emitting element may further include a fourth semiconductor layer arranged on the third semiconductor layer in the first direction, the fourth semiconductor layer being in contact with the second end portion.

The fourth semiconductor layer may be a semiconductor layer doped with an n-type dopant.

The insulative film may include: a first insulative film surrounding outer surfaces of one area of the second semiconductor layer, the first semiconductor layer, and the active layer; and a second insulative film surrounding outer surfaces of an other area of the second semiconductor layer, the third semiconductor layer, and the fourth semiconductor layer. The opening may be between the first insulative film and the second insulative film.

The first pixel electrode may be electrically connected to the first semiconductor layer while being in contact with the first end portion of the light emitting element. The second pixel electrode may be electrically connected to the second semiconductor layer while being in contact with the second semiconductor layer exposed through the opening.

The third semiconductor layer may include at least one of AlGaInN, GaN, AlGaN, InGaN, AlN, or InN. The second pixel electrode may be in contact with the fourth semiconductor layer through the second end portion of the light emitting element.

The first pixel electrode may be an anode electrode, and the second pixel electrode may be a cathode electrode.

In a cross sectional view, the light emitting element may be inclined with respect to the substrate.

The display device may further include an insulating pattern on the light emitting element. In a plan view, the first pixel electrode and the second pixel electrode may respectively cover both ends of the insulating pattern. The insulating pattern may include an organic material.

In a plan view, the opening of the insulative film may not overlap with the insulating pattern.

In a plan view, the first pixel electrode and the insulating pattern may overlap with a portion of the second semiconductor layer of the light emitting element.

In accordance with one or more embodiments of the present disclosure, there is provided a method of manufacturing a display device, the method including: forming, on a substrate, a first alignment electrode and a second alignment electrode that are spaced from each other; forming a first insulating layer over the first alignment electrode and the second alignment electrode; aligning a light emitting element on the first insulating layer between the first alignment electrode and the second alignment electrode by forming an electric field between the first alignment electrode and the second alignment electrode; forming an insulating pattern on one area of the light emitting element; forming an opening in an insulative film of the light emitting element by etching a portion of an outer surface of the light emitting element adjacent to a second pixel electrode; and forming a first pixel electrode in contact with a first end portion of the light emitting element and the second pixel electrode in contact with a second end portion of the light emitting element.

The second pixel electrode may be in contact with a second semiconductor layer of the light emitting element.

The light emitting element may include a first semiconductor layer, an active layer, the second semiconductor layer, and a third semiconductor layer sequentially arranged along a first direction. The insulative film may cover outer surfaces of the first semiconductor layer, the active layer, the second semiconductor layer, and the third semiconductor layer. The first semiconductor layer may be a semiconductor layer doped with a p-type dopant, the second semiconductor layer may be a semiconductor layer doped with an n-type dopant, and the third semiconductor layer may be a semiconductor layer that is not doped. The forming of the opening may include removing the insulative film surrounding at least one side surface of the second semiconductor layer.

The light emitting element may further include a fourth semiconductor layer arranged on the third semiconductor layer in the first direction, the fourth semiconductor layer being at the second end portion. In a plan view, the opening may not overlap with the insulating pattern. The fourth semiconductor layer may a semiconductor layer doped with an n-type dopant.

In the display device and the method of manufacturing the same in accordance with the present disclosure, a light emitting element and a pixel electrode are electrically connected to each other through an opening formed at a side surface portion of the light emitting element, so that a contact resistance between the light emitting element and the pixel electrode, which is caused by the shape of a fracture surface of the light emitting element, can be reduced (or minimized).

Also, in the display device and the method of manufacturing the same in accordance with the present disclosure, as another semiconductor layer for blocking electrical flow between semiconductor layers is included, an electrical short-circuit phenomenon can be prevented, which may occur when the alignment direction of the light emitting element is a reverse direction (e.g., a non-light emission state of the light emitting element).

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that the present disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a perspective cutaway view illustrating a light emitting element in accordance with one or more embodiments of the present disclosure.

FIG. 2 is a sectional view illustrating an example of the light emitting element shown in FIG. 1.

FIG. 3 is a schematic plan view illustrating a display device in accordance with one or more embodiments of the present disclosure.

FIG. 4 is a circuit diagram illustrating an example of a sub-pixel included in the display device shown in FIG. 3.

FIG. 5 is a schematic plan view illustrating an example of the sub-pixel included in the display device shown in FIG. 3.

FIG. 6 is a schematic sectional view illustrating an example of the sub-pixel taken along the line I-I′ shown in FIG. 5.

FIGS. 7 and 8 are sectional views illustrating an example of a light emitting element disposed in the display device shown in FIG. 3.

FIG. 9 is an enlarged view illustrating an embodiment of an area A shown in FIG. 6.

FIG. 10 is an enlarged view illustrating another embodiment of the area A shown in FIG. 6.

FIG. 11 is a sectional view illustrating a pixel included in the display device shown in FIG. 3.

FIGS. 12 to 17 are schematic sectional views illustrating a method of manufacturing the display device in accordance with one or more embodiments of the present disclosure.

### DETAILED DESCRIPTION

Hereinafter, embodiments of the present disclosure will be described in more detail with reference to the accompanying drawings. Throughout the drawings, the same reference numerals are given to the same elements, and their overlapping descriptions will be omitted.

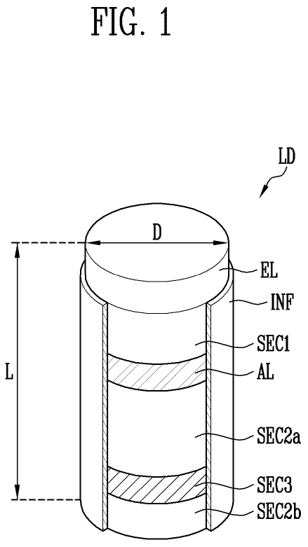

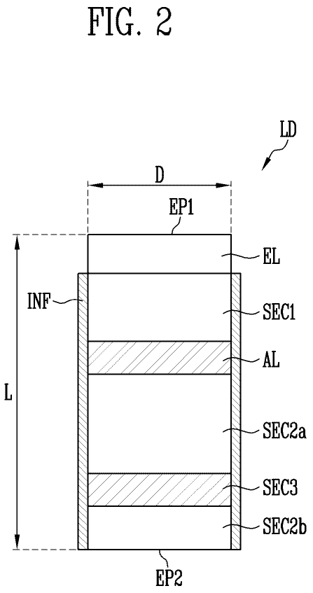

FIG. 1 is a perspective cutaway view illustrating a light emitting element in accordance with one or more embodiments of the present disclosure. FIG. 2 is a sectional view illustrating an example of the light emitting element shown in FIG. 1.

Referring to FIGS. 1 and 2, the light emitting element LD is configured to emit light. For example, the light emitting element LD may be a light emitting diode including an inorganic material.

The light emitting element LD may include a first semiconductor layer SEC1, an active layer AL, a second semiconductor layer SEC2a, a third semiconductor layer SEC3, a fourth semiconductor layer SEC2b, and an electrode layer EL. For example, when assuming that an extending direction of the light emitting element LD is a length L direction, the light emitting element LD may be implemented as a light emitting stack structure (or stack pattern) in which the electrode layer EL, the first semiconductor layer SEC1, the active layer AL, the second semiconductor layer SEC2a, the third semiconductor layer SEC3, and the fourth semiconductor layer SEC2b are sequentially stacked in the length L direction. The light emitting element LD may further include an insulative film INF.

In one or more embodiments, the electrode layer EL may be omitted. The light emitting element LD may include the first semiconductor layer SEC1, the active layer AL, the second semiconductor layer SEC2a, the third semiconductor layer SEC3, and the fourth semiconductor layer SEC2b, which are sequentially stacked in the length L direction.

The light emitting element LD may be provided in a shape extending in one direction. The light emitting element LD may include a first end portion EP1 and a second end portion EP2 along the length L direction. The first semiconductor layer SCE1 may be adjacent to the first end portion EP1 of the light emitting element LD, and the fourth semiconductor layer SEC2b may be adjacent to the second end portion EP2. The electrode layer EL may be adjacent to the first end portion EP1.

The light emitting element LD may be provided in various shapes. In an example, the light emitting element LD may have a rod-like shape, a bar-like shape, a pillar-like shape, or the like, which is long in its length L direction (or of which its aspect ratio is greater than 1) as shown in FIG. 1. In another example, the light emitting element LD may have a rod-like shape, a bar-like shape, a pillar-like shape, or the like, which is short in its length L direction (or of which its aspect ratio is smaller than 1). In still another example, the light emitting element LD may have a rod-like shape, a bar-like shape, a pillar-like shape, or the like, of which aspect ratio is 1.

The light emitting element LD may include, for example, a light emitting diode (LED) manufactured small enough to have a diameter D and/or a length L to a degree of a nano scale (or nanometers) to a micro scale (micrometers).

When the light emitting element LD is long in its length L direction (i.e., when its aspect ratio is greater than 1), the diameter D of the light emitting element LD may be about 0.5 μm to about 6 μm, and the length L of the light emitting element LD may be about 1 μm to about 10 μm. However, the diameter D and the length L of the light emitting element LD are not limited thereto, and the size of the light emitting element LD may be changed in accordance with requirement conditions (or design conditions) of a lighting device or a self-luminous display device, to which the light emitting element LD is applied.

In one or more embodiments, the electrode layer EL may include a metal or a conductive metal oxide, and may be formed, for example, using one or mixture of chromium (Cr), titanium (Ti), aluminum (Al), gold (Au), nickel (Ni), and any oxide or alloy thereof, a transparent electrode material such as indium tin oxide (ITO), indium zinc oxide (IZO), zinc oxide (ZnO), or indium tin zinc oxide (ITZO). The electrode layer EL may be substantially transparent. Accordingly, light generated in the light emitting element LD is transmitted through the electrode layer EL, thereby being emitted to the outside of the light emitting element LD.

In one or more embodiments, the electrode layer EL may include a lower surface on which the first semiconductor layer SEC1 is disposed and a first surface exposed to the outside in the length L direction. The electrode layer EL may be the first end portion EP1 (or top end portion) of the light emitting element LD and may be disposed on the first semiconductor layer SEC1.

The first semiconductor layer SEC1 may include, for example, at least one p-type semiconductor layer. For example, the first semiconductor layer SEC1 may include at least one semiconductor material selected from among InAlGaN, GaN, AlGaN, InGaN, AlN, and InN, and may include a p-type semiconductor layer doped with a first conductivity type dopant such as Mg. The first semiconductor layer SEC1 may include an upper surface exposed to the outside among the length L direction of the light emitting element LD and a lower surface in contact with the active layer AL. The electrode layer EL may be disposed on the upper surface of the first semiconductor layer SEC1 at one end portion (or top end portion) of the light emitting element LD.

The active layer AL may be disposed between the first semiconductor layer SEC1 and the second semiconductor layer SEC2a, and may be formed in a single or multiple quantum well structure. In an example, when the active layer AL is formed in the multiple quantum well structure, a barrier layer, a strain reinforcing layer, and a well layer, which constitute one unit, may be periodically and repeatedly stacked in the active layer AL. The strain reinforcing layer may have a lattice constant smaller than a lattice constant of the barrier layer, thereby further reinforcing strain, e.g., compressive strain applied to the well layer. However, the structure of the active layer AL is not limited to the above-described embodiment.

A clad layer and/or a Tensile Strain Barrier Reducing (TSBR) layer, doped with a conductive dopant, may be further disposed on the top and/or the bottom of the active layer AL. For example, the clad layer may be formed of an ALGaN layer or an ALInGaN layer. The TSBR layer may be a strain reducing layer disposed between semiconductor layers having different lattice structures to perform a reducing function for reducing a lattice constant difference. The TSBR layer may be configured with a p-type semiconductor layer such as p-GaInP, p-AlInP or p-AlGaInP, but the present disclosure is not limited thereto.

The active layer AL may emit light having a wavelength of about 400 nm to about 900 nm, and use a double hetero structure. The active layer AL may include a first surface in contact with the first semiconductor layer SEC1 and a second surface in contact with the second semiconductor layer SEC2a.

A color (or light emission color) of the light emitting element LD may be determined according to the wavelength of light emitted in the active layer AL. The color of the light emitting element LD may determine a color of a pixel corresponding thereto. For example, the light emitting element LD may emit red light, green light, or blue light.

When an electric field having a suitable voltage (e.g., a predetermined voltage) or more is applied to both the end portions of the light emitting element LD, the light emitting element LD emits light as electron-hole pairs are combined in the active layer AL. The light emission of the light emitting element LD is controlled by using such a principle, so that the light emitting element LD can be used as a light source (or light emitting source) for various light emitting devices, including a pixel of a display device.

The second semiconductor layer SEC2a (or (2-1)th semiconductor layer) may be disposed on the second surface of the active layer AL, and may include a semiconductor layer having a type different from the type of the first semiconductor layer SEC1. In an example, the second semiconductor layer SEC2a may include at least one n-type semiconductor layer. The second semiconductor layer SEC2a may include any one semiconductor material selected from among InAlGaN, GaN, AlGaN, InGaN, AlN, and InN, and may include an n-type semiconductor layer doped with a second conductivity type dopant such as Si, Ge or Sn. However, the material for forming the second semiconductor layer SEC2a is not limited thereto. In addition, the second semiconductor layer SEC2a may be configured with various materials.

The second semiconductor layer SEC2a may include an upper surface in contact with the second surface of the active layer AL and a lower surface in contact with the third semiconductor layer SEC3.

The first semiconductor layer SEC1 and the second semiconductor layer SEC2a may have different thicknesses in the length L direction of the light emitting element LD. In an example, the second semiconductor layer SEC2a may have a thickness relatively thicker than a thickness of the first semiconductor layer SEC1 along the length L direction of the light emitting element LD. Accordingly, the active layer AL of the light emitting element LD may be located more adjacent to the upper surface of the first semiconductor layer SEC1 than the lower surface of the second semiconductor layer SEC2a.

The third semiconductor layer SEC3 may be disposed between the second semiconductor layer SEC2a and the fourth semiconductor layer SEC2b. The third semiconductor layer SEC3 may prevent a current from flowing from the second semiconductor layer SEC2a to the second end portion EP2. Also, the third semiconductor layer SEC3 may prevent a current applied through the fourth semiconductor layer SEC2b as the second end portion EP2 from flowing into the second semiconductor layer SEC2a. The third semiconductor layer SEC3 may be a semiconductor layer doped with no dopant. The third semiconductor layer SEC3 may include at least one of AlGaInN, GaN, AlGaN, InGaN, AlN, or InN. The third semiconductor layer SEC3 may include a material having a band gap energy higher than a band gap energy of each of the second semiconductor layer SEC2a and the fourth semiconductor layer SEC2b. Thus, electrons injected into the third semiconductor layer SEC3 can be prevented from flowing into the second semiconductor layer SEC2a and the fourth semiconductor layer SEC2b.

The third semiconductor layer SEC3 may include a first surface in contact with the second semiconductor layer SEC2a and a second surface in contact with the fourth semiconductor layer SEC2b.

The second semiconductor layer SEC2a and the third semiconductor layer SEC3 may have different thicknesses in the length L direction of the light emitting element LD. In an example, the second semiconductor layer SEC2a may have a thickness relatively thicker than a thickness of the third semiconductor layer SEC3. In an example, the third semiconductor layer SEC3 may have the substantially same thickness as the first semiconductor layer SEC1 in the length L direction, but the present disclosure is not limited thereto.

The fourth semiconductor layer SEC2b (or (2-2)th semiconductor layer) may include a first surface (upper surface) on which the third semiconductor layer SEC3 is disposed and a second surface (lower surface) exposed to the outside in the length L direction. The fourth semiconductor layer SEC2b may be the second end portion EP2 (or bottom end portion) of the light emitting element LD.

The fourth semiconductor layer SEC2b may include at least one n-type semiconductor layer. The fourth semiconductor layer SEC2b may include at least one semiconductor material selected from among InAlGaN, GaN, AlGaN, InGaN, AlN, and InN, and include an n-type semiconductor layer doped with a second conductivity type dopant such as Si, Ge or Sn. However, the material for forming the fourth semiconductor layer SEC2b is not limited thereto. In addition, the fourth semiconductor layer SEC2b may be configured with various materials.

An insulative film INF (or an insulative film of the light emitting element) may be disposed on a surface of the light emitting element LD. The insulative film INF may be provided and/or formed to be around (e.g., to surround) outer surfaces (e.g., outer peripheral or circumferential surfaces) of the first semiconductor layer SEC1, the active layer AL, the second semiconductor layer SEC2a, the third semiconductor layer SEC3, and the fourth semiconductor layer SEC2b.

The insulative film INF may expose each of the first end portion EP1 and the second end portion EP2 of the light emitting element LD. In an example, one area of the electrode layer EL corresponding to the first end portion EP1 may be exposed from the insulative film INF.

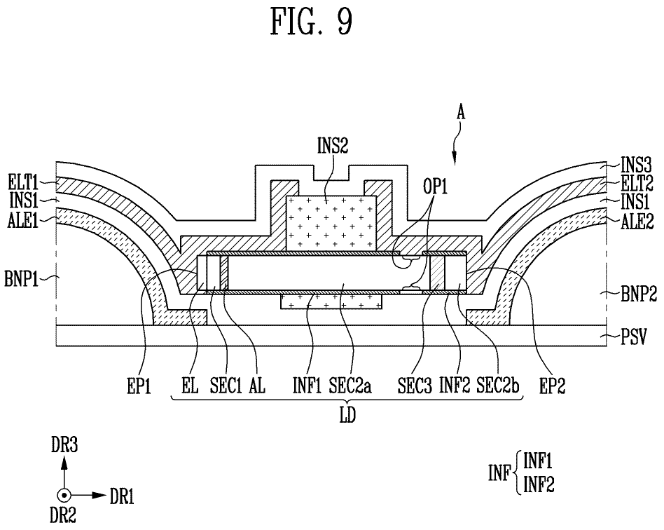

In FIGS. 1 and 2, it is described that the insulative film INF entirely surrounds an outer surface (e.g., an outer peripheral or circumferential surface) of the light emitting stack structure of the light emitting element LD. However, the present disclosure is not limited thereto. For example, one side surface of the second semiconductor layer SEC2a may be exposed to the outside by an opening (e.g., an opening OP1 shown in FIG. 9) formed in the insulative film INF.

The insulative film INF may include a transparent insulating material. For example, the insulative film INF may include at least one insulating material selected from the group consisting of silicon oxide (SiOₓ), silicon nitride (SiNₓ), silicon oxynitride (SiOₓN_{y}), aluminum oxide (AlOₓ), titanium dioxide (TiO₂), hafnium oxide (HfOₓ), titanium strontium oxide (SrTiOₓ), cobalt oxide (CoₓO_{y}), magnesium oxide (MgO), zinc oxide (ZnO), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InxOy:H, niobium oxide (NbₓO_{y}), magnesium fluoride (MgFₓ), aluminum fluoride (AlFₓ), Alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), vanadium nitride (VN), and the like. However, the present disclosure is not limited thereto, and various materials having insulating properties may be used as the material of the insulative film INF.

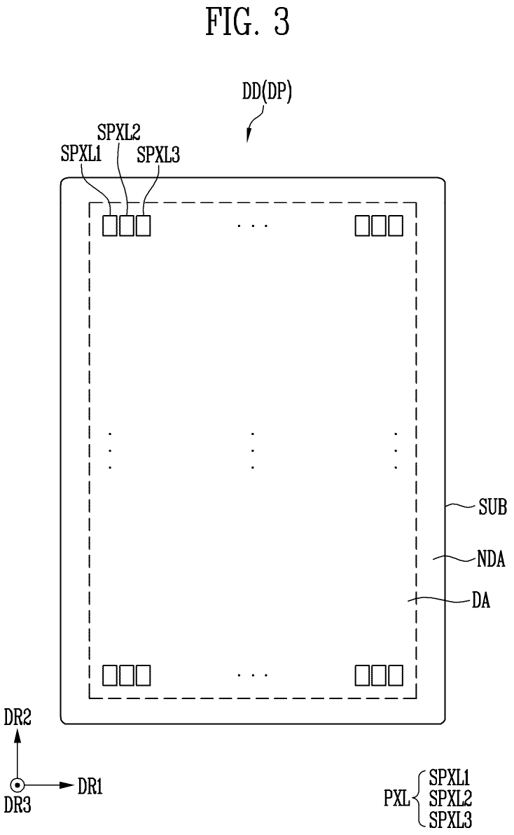

FIG. 3 is a schematic plan view illustrating a display device in accordance with embodiments of the present disclosure.

In FIG. 3, a structure of a display panel DP will be briefly illustrated based on a display area DA. However, in some embodiments, at least one driving circuit (e.g., at least one of a scan driver and a data driver), lines, and/or pads, which are not shown, may be further disposed in the display panel PD.

The present disclosure may be applied as long as the display device DD is an electronic device in which a display surface is applied to at least one surface thereof, such as a smartphone, a television, a tablet personal computer (PC), a mobile phone, a video phone, an electronic book reader, a desktop PC, a laptop PC, a netbook computer, a workstation, a server, a personal digital assistant (PDA), a portable multimedia player (PMP), an MP3 player, a medical device, a camera, or a wearable device.

Referring to FIG. 3, the display panel DP may include a substrate SUB (or base layer) and pixels PXL provided on the substrate SUB.

The display panel DP may have various shapes. In an example, the display panel DP may be provided in a rectangular plate shape, but the present disclosure is not limited thereto. For example, the display panel DP may have a shape such as a circular shape or an elliptical shape. Also, the display panel DP may include an angular corner and/or a curved corner. For convenience, in FIG. 3, it is illustrated that the display panel DP has a rectangular plate shape. Also, in FIG. 3, an extending direction (e.g., a lateral direction) of a short side of the display panel DP is designated as a first direction DR1, and an extending direction (e.g., a longitudinal direction) of a long side of the display panel DP is designated as a second direction DR2.

The substrate SUB is used to constitute a base member of the display panel DP, and may be a rigid or flexible substrate or film. In an example, the substrate SUB may be configured as a rigid substrate made of glass or tempered glass, a flexible substrate (or thin film) made of plastic or metal, or at least one insulating layer. The material and/or property of the substrate SUB is not particularly limited.

The substrate SUB (and the display panel DP) may include the display area DA for displaying an image and a non-display area NDA except the display area DA and may be disposed along an edge or periphery of the display area DA. The display area DA may constitute a screen on which an image is displayed, and the non-display area NDA may be located at least one side of the display area DA. For example, the non-display area NDA may surround the display area DA, but the present disclosure is not limited thereto.

The pixels PXL may be disposed in the display area DA on the substrate SUB. The non-display area NDA may be disposed at the periphery of the display area DA. Various lines, pads, and/or a built-in circuit, which are connected to the pixels PXL of the display area DA, may be disposed in the non-display are NDA.

In the embodiments of the present disclosure, the term “connection (or access)” may inclusively mean physical and/or electrical connection (or access). Also, this may inclusively mean direct or indirect connection (or access) and integral or non-integral connection (or access).

The pixel PXL may include sub-pixels SPXL1 to SPXL3. For example, the pixel PXL may include a first sub-pixel SPXL1, a second sub-pixel SPXL2, and a third sub-pixel SPXL3.

Each of the sub-pixels SPXL1 to SPXL3 may emit light of a desired color (e.g., a predetermined color). In one or more embodiments, the sub-pixels SPXL1 to SPXL3 may emit lights of different colors. In an example, the first sub-pixel SPXL1 may emit light of a first color, the second sub-pixel SPXL2 may emit light of a second color, and the third sub-pixel SPXL3 may emit light of a third color. For example, the first sub-pixel SPXL1 may be a red pixel emitting light of red, the second sub-pixel SPXL2 may be a green pixel emitting light of green, and the third sub-pixel SPXL3 may be a blue pixel emitting light of blue. However, the present disclosure is not limited thereto.

The first sub-pixel SPXL1, the second sub-pixel SPXL2, and the third sub-pixel SPXL3 may have, as light sources, a light emitting element of the first color, a light emitting element of the second color, and a light emitting element of the third color, to emit lights of the first color, the second color, and the third color, respectively. In one or more embodiments, the first sub-pixel SPXL1, the second sub-pixel SPXL2, and the third sub-pixel SPXL3 may have light emitting elements emitting light of the same color and include color conversion layers and/or color filters of different colors, which are disposed above the respective light emitting elements, to respectively emit lights of the first color, the second color, and the third color. However, the color, kind (or type), and/or number of sub-pixels SPXL1 to SPXL3 constituting each pixel PXL are not particularly limited. That is, the color of light emitted by each pixel PXL may be variously changed.

The sub-pixels SPXL1 to SPXL3 may be regularly arranged according to a stripe structure, a PENTILE® structure, or the like. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. For example, the sub-pixels SPXL1, SPXL2, and SPXL3 may be sequentially and repeatedly disposed along a first direction DR1. Also, the first, second, and third sub-pixels SPXL1, SPXL2, and SPXL3 may be repeatedly disposed along a second direction DR2. At least one first sub-pixel SPXL1, at least one second sub-pixel SPXL2, and at least one third sub-pixel SPXL3, which are disposed adjacent to each other, may constitute one pixel PXL capable of emitting lights of various colors. However, the arrangement structure of the sub-pixels SPXL1 to SPXL3 is not limited thereto, and the sub-pixels SPXL1 to SPXL3 may be arranged in the display area DA in various structures and/or various manners.

Each of the sub-pixels SPXL1 to SPXL3 may be configured as an active pixel. For example, each of the sub-pixels SPXL1 to SPXL3 may include at least one light source (e.g., at least one light emitting element) driven by a suitable control signal (e.g., a predetermined control signal, e.g., a scan signal and a data signal) and/or a suitable power source (e.g., a predetermined power source, e.g., a first power source and a second power source). However, the kind (or type), structure, and/or driving method of the sub-pixels SPXL1 to SPXL3, which can be applied to the display device, are not particularly limited.

Hereinafter, when a first sub-pixel SPXL1, a second sub-pixel SPXL2, and a third sub-pixel SPXL3 are inclusively designated, each of the first, second, and third sub-pixels SPXL1, SPXL2, and SPXL3 or the first, second, and third sub-pixels SPXL1, SPXL2, and SPXL3 will be referred to as a sub-pixel SPXL or sub-pixels SPXL.

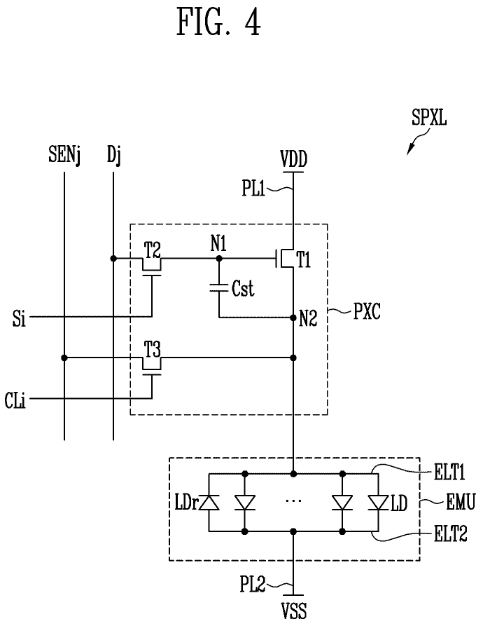

FIG. 4 is a circuit diagram illustrating an example of the sub-pixel included in the display device shown in FIG. 3.

Referring to FIGS. 1 to 4, the sub-pixel SPXL may include a light emitting unit EMU which generates light with a luminance corresponding to a data signal. Also, the sub-pixel SPXL may selectively further include a pixel circuit PXC for driving the light emitting unit EMU.

The light emitting unit EMU may include a plurality of light emitting elements LD connected in parallel between a first power line PL1 connected to a first driving power source VDD to be applied with a voltage of the first driving power source VDD and a second power line PL2 connected to a second driving power source VSS to be applied with a voltage of the second driving power source VSS. For example, the light emitting unit EMU may include a first connection electrode ELT1 connected to the first driving power source VDD via the pixel circuit PXC and the first power line PL1, a second connection electrode ELT2 connected to the second driving power source VSS through the second power line PL2, and a plurality of light emitting elements LD connected in parallel in the same direction between the first and second connection electrodes ELT1 and ELT2. In one or more embodiments, the first connection electrode ELT1 may be an anode, and the second connection electrode ELT2 may be a cathode.

Each of the light emitting elements LD included in the light emitting unit EMU may include one end portion connected to the first driving power source VDD through the first connection electrode ELT1 and the other end portion connected to the second driving power source VSS through the second connection electrode ELT2. The first driving power source VDD and the second driving power source VSS may have different potentials. In an example, the first driving power source VDD may be set as a high-potential power source, and the second driving power source VSS may be set as a low-potential power source. A potential difference between the first and second driving power sources VDD and VSS may be set equal to or higher than a threshold voltage of the light emitting elements LD during an emission period of the pixel PXL.

As described above, the light emitting elements LD connected in parallel in the same direction (e.g., a forward direction) between the first connection electrode ELT1 and the second connection electrode ELT2, to which voltages having difference potentials are supplied, may form respective effective light sources.

In one or more embodiments, each of the light emitting elements LD of the light emitting unit EMU may emit light with a luminance corresponding to a driving current supplied through a corresponding pixel circuit PXC. For example, the pixel circuit PXC may supply, to the light emitting unit EMU, a driving current corresponding to a grayscale value of corresponding frame data during each frame period. The driving current supplied to the light emitting unit EMU may be divided to flow through each of the light emitting elements LD. Accordingly, the light emitting unit EMU can emit light with a luminance corresponding to the driving current while each light emitting element LD is emitting light with a luminance corresponding to a current flowing therethrough.

Although a case where both the end portions of the light emitting elements LD are connected in the same direction between the first and second driving power sources VDD and VSS has been described in the above-described embodiment, but the present disclosure is not limited thereto. In one or more embodiments, the light emitting unit EMU may further include at least one ineffective light source, e.g., a reverse light emitting element LDr, in addition to the light emitting elements LD forming the respective effective light sources. The reverse light emitting element LDr is connected in parallel together with the light emitting elements LD forming the effective light sources between the first and second connection electrodes ELT1 and ELT2, and may be connected between the first and second connection electrodes ELT1 and ELT2 in a direction opposite to that in which the light emitting elements LD are connected. Although a predetermined driving voltage (e.g., a forward driving voltage) is applied between the first and second connection electrodes ELT1 and ELT2, the reverse light emitting element LDr maintains an inactivated state, and accordingly, no current substantially flows through the reverse light emitting element LDr.

The pixel circuit PXC may be connected to a scan line Si and a data line Dj of the pixel PXL. Also, the pixel circuit PXC may be connected to a control line CLi and a sensing line SENj of the pixel PXL. In an example, when the pixel PXL is disposed on an ith row and a jth column of the display area DA, the pixel circuit PXC of the pixel PXL may be connected an ith scan line Si, a jth data line Dj, an ith control line CLi, and a jth sensing line SENj of the display area DA.

The pixel circuit PXC may include first to third transistors T1 to T3 and a storage capacitor Cst.

The first transistor T1 is a driving transistor for controlling a driving current applied to the light emitting unit EMU, and may be connected between the first driving power source VDD and the light emitting unit EMU. Specifically, a first terminal of the first transistor T1 may be connected (or coupled) to the first driving power source VDD through the first power line PL1, a second terminal of the first transistor T1 may be connected to a second node N2, and a gate electrode of the first transistor T1 may be connected to a first node N1. The first transistor T1 may control an amount of driving current applied to the light emitting unit EMU through the second node N2 from the first driving power source VDD according to a voltage applied to the first node N1. In one or more embodiments, the first terminal of the first transistor T1 may be a drain electrode, and the second terminal of the first transistor T1 may be a source electrode. However, the present disclosure is not limited thereto. In one or more embodiments, the first terminal may be the source electrode, and the second terminal may be the drain electrode.

The second transistor T2 is a switching transistor which selects a pixel PXL in response to a scan signal and activates the pixel PXL, and may be connected between the data line Dj and the first node N1. A first terminal of the second transistor T2 may be connected to the data line Dj, a second terminal of the second transistor T2 may be connected to the first node N1, and a gate electrode of the second transistor T2 may be connected to the scan line Si. The first terminal and the second terminal of the second transistor T2 are different terminals. For example, when the first terminal is a drain electrode, the second terminal may be a source electrode.

The second transistor T2 may be turned on when a scan signal having a gate-on voltage (e.g., a high level voltage) is supplied from the scan line Si, to electrically connect the data line Dj and the first node N1 to each other. The first node N1 is a point at which the second terminal of the second transistor T2 and the gate electrode of the first transistor T1 are connected to each other, and the second transistor T2 may transfer a data signal to the gate electrode of the first transistor T1.

The third transistor T3 connects the first transistor T1 to the sensing line SENj, to acquire a sensing signal through the sensing line SENj and to detect a characteristic of the pixel PXL, including a threshold voltage of the first transistor, or the like, by using the sensing signal. Information on the characteristic of the pixel PXL may be used to convert image data such that a characteristic deviation between pixels PXL can be compensated. A second terminal of the third transistor T3 may be connected to the second terminal of the first transistor T1 and the second node N2, a first terminal of the third transistor T3 may be connected to the sensing line SENj, and a gate electrode of the third transistor T3 may be connected to the control line CLi. Also, the first terminal of the third transistor T3 may be connected to an initialization power source. The third transistor T3 is an initialization transistor capable of initializing the second node N2. The third transistor T3 may be turned on when a sensing control signal is supplied from the control line CLi, to transfer a voltage of the initialization power source to the second node N2. Accordingly, a second storage electrode of the storage capacitor Cst, which is connected to the second node N2, may be initialized.

A first storage electrode of the storage capacitor Cst may be connected to the first node N1, and the second storage electrode of the storage capacitor Cst may be connected to the second node N2. The storage capacitor Cst charges a data voltage corresponding to the data signal supplied to the first node N1 during one frame period. Accordingly, the storage capacitor Cst may store a voltage corresponding to the difference between a voltage of the gate electrode of the first transistor T1 and a voltage of the second node N2.

Although an embodiment in which the light emitting elements LD constituting the light emitting unit EMU are all connected in parallel has been illustrated in FIG. 4, the present disclosure is not limited thereto. In one or more embodiments, the light emitting unit EMU may be configured to include at least one serial stage (or stage) including a plurality of light emitting elements LD connected in parallel to each other. That is, the light emitting unit EMU may be configured in a series/parallel hybrid structure.

Although a case where the transistors T1 to T3 included in the pixel circuit PXC are all n-type transistors has been illustrated in FIG. 4, the present disclosure is not necessarily limited thereto. For example, at least one of the transistors T1 to T3 may be changed to a p-type transistor.

In addition, the structure and driving method of the sub-pixel SPXL may be variously changed. For example, the pixel circuit PXC may be configured as a pixel circuit having various structures and/or various driving methods, in addition to the embodiment shown in FIG. 4.

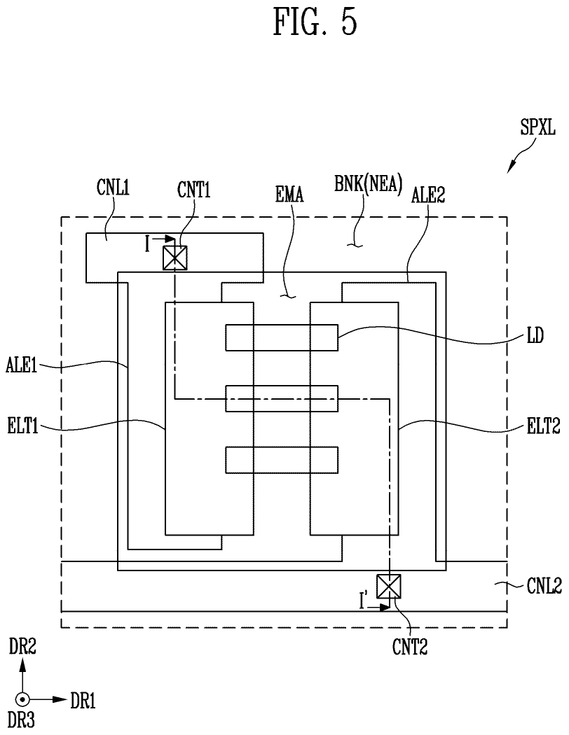

FIG. 5 is a schematic plan view illustrating an example of the sub-pixel included in the display device shown in FIG. 3. FIG. 5 is a view illustrating some components included in the sub-pixel SPXL.

Referring to FIG. 5, the sub-pixel SPXL may include a bank BNK, first and second pixel electrodes ELT1 and ELT2, first and second alignment electrode ALE1 and ALE2, first and second connection electrodes CNL1 and CNL2, and light emitting elements LD.

The bank BNK may partition sub-pixels SPXL, and an emission area EMA may correspond to an opening defined by the bank BNK. In an example, the bank BNK may form a space in which a fluid can be accommodated. For example, during a manufacturing process, ink including the light emitting elements LD may be provided in the space in which the fluid can be accommodated.

A non-emission area NEA may be an area substantially corresponding to the bank BNK. When viewed on a plane (e.g., in a plan view), the bank BNK may surround the emission area EMA.

The sub-pixel SPXL may include the first and second alignment electrodes ALE1 and ALE2. In an example, the first and second alignment electrodes ALE1 and ALE2 may serve as electrodes for aligning the light emitting elements LD and electrodes for applying a suitable voltage (e.g., a predetermined voltage).

The first and second alignment electrodes ALE1 and ALE2 may extend in the second direction DR2, and may be disposed to be spaced from each other in the first direction DR1.

The first connection electrode CNL1 may be disposed in the same layer as the first alignment electrode ALE1 to be integrally formed. The second connection electrode CNL2 may be disposed in the same layer as the second alignment electrode ALE2 to be integrally formed.

The first and second alignment electrodes ALE1 and ALE2 may serve as alignment electrodes for the light emitting elements LD. For example, the light emitting elements LD may be arranged based on an electrical signal provided to the first and second alignment electrodes ALE1 and ALE2.

The light emitting elements LD may be arranged in a parallel structure along the second direction DR2. The arrangement structure of the light emitting elements LD is not limited thereto.

The light emitting elements LD may be disposed between (or on) the first and second alignment electrodes ALE1 and ALE2 when viewed on a plane (e.g., in a plan view).

In one or more embodiments, the first pixel electrode ELT1 may be disposed on the first alignment electrode ALE1 when viewed on a plane (e.g., in a plan view) to be electrically connected to the first alignment electrode ALE1. The second pixel electrode ELT2 may be disposed on the second alignment electrode ALE2 when viewed on a plane (e.g., in a plan view) to be electrically connected to the second alignment electrode ALE2.

The light emitting element LD may be electrically connected to the first alignment electrode ALE1 through the first pixel electrode ELT1, and be electrically connected to the second alignment electrode ALE2 through the second pixel electrode ELT2.

A first end portion (e.g., the first end portion EP1 shown in FIG. 1) (or a second end portion (e.g., the second end portion EP2 shown in FIG. 1)) of the light emitting element LD may be electrically connected to the first pixel electrode ELT1. The second end portion EP2 (or the first end portion EP1) of the light emitting element LD may be electrically connected to the second pixel electrode ELT2.

A first semiconductor layer (e.g., the first semiconductor layer SEC1 shown in FIG. 1 (e.g., via the electrode layer EL)) or a fourth semiconductor layer (e.g., the fourth semiconductor layer SEC2b shown in FIG. 1) of the light emitting element LD may be electrically connected to the first pixel electrode ELT1.

The first and second alignment electrodes ALE1 and ALE2 may be electrically connected to a pixel circuit PXC and/or a power line. For example, the first alignment electrode ALE1 may be electrically connected to the pixel circuit PXC and/or a first power line PL1 through a first contact hole CNT1 formed in the first connection electrode CNL1, and the second alignment electrode ALE2 may be electrically connected to the pixel circuit PXC and/or a second power line PL2 through a second contact hole CNT2 formed in the second connection electrode CNL2.

In FIG. 5, it is illustrated that the first pixel electrode ELT1 is connected to the first power line PL1 through the first alignment electrode ALE1 and the second pixel electrode ELT2 is connected to the second power line PL2 through the second alignment electrode ALE2. However, the present disclosure is not limited thereto. For example, the first pixel electrode ELT1 does not go through the first alignment electrode ALE1, but may be directly connected to the first power line PL1 through a separate contact part. In one or more embodiments, the second pixel electrode ELT2 does not go through the second alignment electrode ALE2, but may be directly connected to the second power line PL1 through a separate contact part.

When alight emitting element LD is provided in the sub-pixel SPXL, the light emitting element LD may be arranged in a forward direction between the first and second alignment electrodes ALE1 and ALE2, or may be arranged in a reverse direction between the first and second alignment electrodes ALE1 and ALE2. When the light emitting element LD is arranged in the forward direction, the light emitting element LD may constitute an effective light source. When the light emitting element LD is arranged in the reverse direction, the light emitting element LD may constitute a non-effective light source.

In this specification, the state in which the light emitting element LD is arranged in the forward direction means a case where the first semiconductor layer SCE1 (see FIG. 1) is electrically connected to the first pixel electrode ELT1 (e.g., via the electrode layer EL) and the fourth semiconductor layer SEC2b (see FIG. 2) is electrically connected to the second pixel electrode ELT2, and the state in which the light emitting element LD is arranged in the reverse direction means a case where the fourth semiconductor layer SEC2b is electrically connected to the first pixel electrode ELT1 and the first semiconductor layer SEC1 is electrically connected to the second pixel electrode ELT2 (e.g., via the electrode layer EL).

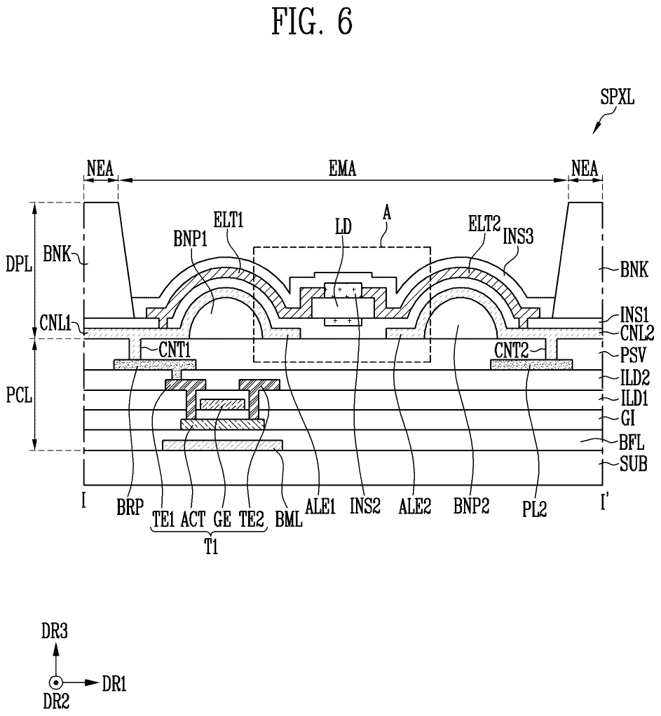

FIG. 6 is a schematic sectional view illustrating an example of the sub-pixel taken along the line I-I′ shown in FIG. 5.

Referring to FIGS. 4 to 6, the sub-pixel SPXL may include a substrate SUB, a pixel circuit layer PCL, and a display element layer DPL. Hereinafter, for convenience of description, the first transistor T1 from among the first to third transistors T1 to T3 described above will be mainly described.

The substrate SUB may constitute a base member of the display device DD. The substrate SUB may be a rigid or flexible substrate or film, but the present disclosure is not limited to a specific example. In an example, the substrate SUB may include polyimide. The substrate SUB may be provided as a base surface, so that the pixel circuit layer PCL and the display element layer DPL are disposed on the substrate SUB.

The pixel circuit layer PCL may be disposed on the substrate SUB. The pixel circuit layer PCL may include a lower electrode layer BML, a buffer layer BFL, the transistor T1, a gate insulating layer GI, a first interlayer insulating layer ILD1, a second interlayer insulating layer ILD2, a bridge pattern BRP, a second power line PL2, a protective layer PSV, a first contact part CNT1, and a second contact part CNT2.

The lower electrode layer BML may be disposed on the substrate SUB, to be covered by the buffer layer BFL. A portion of the lower electrode layer BML may overlap with the first transistor T1 when viewed on a plane (e.g., in a plan view) or in a thickness direction of the substrate SUB (e.g., the third direction DR3).

The lower electrode layer BML may include a conductive material, thereby serving as a path through which an electrical signal provided to the pixel circuit layer PCL and the display element layer DPL moves. For example, the lower electrode layer BML may include at least one of aluminum (Al), copper (Cu), titanium (Ti), or molybdenum (Mo).

The buffer layer BFL may be disposed on the substrate SUB and covers the lower electrode layer BML. The buffer layer BFL may prevent an impurity from being diffused from the outside. The buffer layer BFL may include at least one of silicon nitride (SiNₓ), silicon oxide (SiOₓ), silicon oxynitride (SiOₓN_{y}), or a metal oxide such as aluminum oxide (AlOₓ).

The first transistor T1 may be electrically connected to a light emitting element LD. The first transistor T1 may be electrically connected to the bridge pattern BRP. However, the present disclosure is not limited to the above-described example. The first transistor T1 does not pass through the bridge pattern BRP, but may be electrically connected to a first connection electrode CNL1.

The first transistor T1 may include an active layer ACT, a first transistor electrode TE1, a second transistor electrode TE2, and a gate electrode GE.

The active layer ACT may be a semiconductor layer. The active layer ACT may be disposed on the buffer layer BFL. For example, the active layer ACT may include at least one of Low Temperature Polycrystalline Silicon (LTPS), poly-silicon, amorphous silicon, or an oxide semiconductor.

The active layer ACT may include a first contact region in contact with the first transistor electrode TE1 and a second contact region in contact with the second transistor electrode TE2. The first contact region and the second contact region may correspond to a semiconductor pattern doped with an impurity. A region between the first contact region and the second contact region may be a channel region. The channel region may correspond to an intrinsic semiconductor pattern undoped with the impurity.

The gate electrode GE may be disposed on the gate insulating layer GI. A position of the gate electrode GE may correspond to that of the channel region of the active layer ACT. For example, the gate electrode GE may be disposed on the channel region of the active layer ACT with the gate insulating layer GI interposed therebetween. In an example, the gate electrode GE may include at least one of aluminum (Al), copper (Cu), titanium (Ti), or molybdenum (Mo).

The gate insulating layer GI may be disposed over the active layer ACT and the buffer layer BFL. The gate insulating layer GI may include an inorganic material. In an example, the gate insulating layer GI may include at least one of silicon nitride (SiNₓ), silicon oxide (SiOₓ), silicon oxynitride (SiOₓN_{y}), or aluminum oxide (AlOₓ).

The first interlayer insulating layer ILD1 may be located over the gate electrode GE and the gate insulating layer GI. Like the gate insulating layer GI, the first interlayer insulating layer ILD1 may include at least one of silicon nitride (SiNₓ), silicon oxide (SiOₓ), silicon oxynitride (SiOₓN_{y}), or aluminum oxide (AlOₓ).

The first transistor electrode TE1 and the second transistor electrode TE2 may be located on the first interlayer insulating layer ILD1. The first transistor electrode TE1 may be in contact with the first contact region of the active layer ACT while penetrating the gate insulating layer GI and the first interlayer insulating layer ILD1, and the second transistor electrode TE2 may be in contact with the second contact region of the active layer ACT while penetrating the gate insulating layer GI and the first interlayer insulating layer ILD1. In an example, the first transistor electrode TE1 may be a drain electrode, and the second transistor electrode TE2 may be a source electrode. However, the present disclosure is not limited thereto.

The second interlayer insulating layer ILD2 may be located over the first transistor electrode TE1 and the second transistor electrode TE2, and the first interlayer insulating layer ILD1. Like the first interlayer insulating layer ILD1 and the gate insulating layer GI, the second interlayer insulating layer ILD2 may include an inorganic material. The inorganic material may include at least one of the materials exemplified as the material constituting the first interlayer insulating layer ILD1 and the gate insulating layer GI.

The bridge pattern BRP may be disposed on the second interlayer insulating layer ILD2. The bridge pattern BRP may be connected to the first transistor electrode TE1 through a contact hole penetrating the second interlayer insulating layer ILD2. The bridge pattern BRP may be electrically connected to the first connection electrode CNL1 through the first contact part CNT1 formed in the protective layer PSV.

The second power line PL2 may be disposed on the second interlayer insulating layer ILD2. The second power line PL2 may be electrically connected to a second connection electrode CNL2 through the second contact part CNT2 formed in the protective layer PSV. The second power line PL2 may provide a second power source (or cathode signal) to the light emitting element LD through a second pixel electrode ELT2.

The protective layer PSV may be located on the second interlayer insulating layer ILD2. The protective layer PSV may cover the bridge pattern BRP and the second power line PL2, and the second interlayer insulating layer ILD2. The protective layer PSV may be a via layer. The protective layer PSV may be provided in a form including an organic insulating layer, an inorganic insulating layer, or the organic insulating layer disposed on the inorganic insulating layer, but the present disclosure is not limited thereto.

The first contact part CNT1 connected to one region of the bridge pattern BRP and the second contact part CNT2 connected to one region of the second power line PL2 may be formed in the protective layer PSV.

The display element layer DPL may be disposed on the pixel circuit layer PCL. The display element layer DPL may include first and second bank patterns BNP1 and BNP2, a bank BNK, the first and second connection electrodes CNL1 and CNL2, first and second alignment electrodes ALE1 and ALE2, a first pixel electrode ELT1, the second pixel electrode ELT2, the light emitting element LD, and first, second, and third insulating layers INS1, INS2, and INS3.

The first and second bank patterns BNP1 and BNP2 may be disposed on the protective layer PSV. The first and second bank patterns BNP1 and BNP2 may have a shape protruding in a display direction (e.g., a third direction DR3). In an example, the first and second bank patterns BNP1 and BNP2 may include an organic material and/or an inorganic material, but the present disclosure is not limited thereto.

The first and second connection electrodes CNL1 and CNL2 may be disposed on the protective layer PSV. The first connection electrode CNL1 may be connected to the first alignment electrode ALE1. The first connection electrode CNL1 may be electrically connected to the bridge pattern BRP through the first contact part CNT1. The first connection electrode CNL1 may electrically connect the bridge pattern BRP and the first alignment electrode ALE1 to each other. The second connection electrode CNL2 may be connected to the second alignment electrode ALE2. The second connection electrode CNL2 may be electrically connected to the second power line PL2 through the second contact part CNT2. The second connection electrode CNL2 may electrically connect the second power line PL2 and the second alignment electrode ALE2 to each other.

The first and second alignment electrodes ALE1 and ALE2 may be disposed on the protective layer PSV (or a base layer). At least a portion of the first alignment electrode ALE1 may be arranged over the first bank pattern BNP1, and at least a portion of the second alignment electrode ALE2 may be arranged over the second bank pattern BNP2, so that each of the first alignment electrode ALE1 and the second alignment electrode ALE2 serves as a reflective partition wall.

The first alignment electrode ALE1 may be electrically connected to the first pixel electrode ELT1 through a contact hole formed in the first insulating layer INS1. The first pixel electrode ELT1 may receive an anode signal of the light emitting element LD through the first alignment electrode ALE1.

The second alignment electrode ALE2 may be electrically connected to the second pixel electrode ELT2 through a contact hole formed in the first insulating layer INS1. The second pixel electrode ELT2 may receive a cathode signal (e.g., a ground signal) of the light emitting element LD through the second alignment electrode ALE2.

The first and second alignment electrodes ALE1 and ALE2 may include a conductive material. For example, the first and second alignment electrodes ALE1 and ALE2 may include at least one of silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or alloys thereof. However, the present disclosure is not limited to the above-described example.

The first insulating layer INS1 may be disposed on the protective layer PSV on the first and second connection electrodes CNL1 and CNL2, and first and second alignment electrodes ALE1 and ALE2. The first insulating layer INS may cover the first and second alignment electrodes ALE1 and ALE2. The first insulating layer INS1 may include at least one of silicon oxide (SiOₓ), silicon nitride (SiNₓ), silicon oxynitride (SiOₓN_{y}), or aluminum oxide (AlOₓ).

The bank BNK may be disposed on the first insulating layer INS1. The bank BNK may include an opening which has a constant thickness in the display direction (e.g., the third direction DR3) and corresponds to an emission area EMA. The bank BNK may include an organic material or an inorganic material, but the present disclosure is not limited thereto.

The light emitting element LD may be disposed on the first insulating layer INS1 between the first and second alignment electrodes ALE1 and ALE2, to emit light, based on an electrical signal provided from the first and second pixel electrodes ELT1 and ELT2.

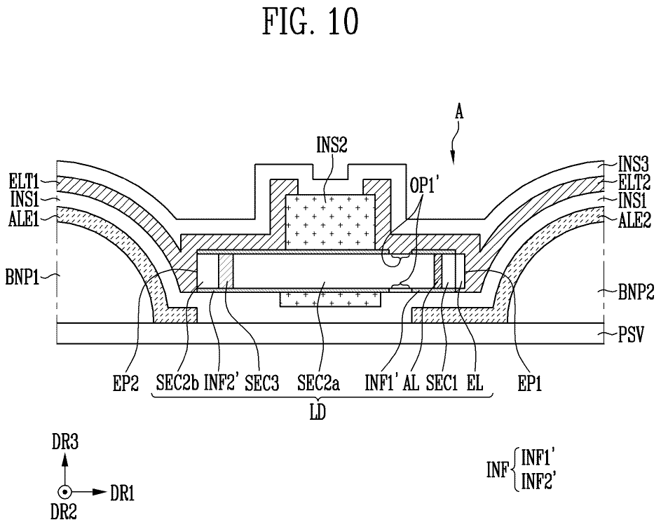

The light emitting element LD may be arranged in a forward direction or a reverse direction between the first and second alignment electrodes ALE1 and ALE2. This will be described later with reference to FIGS. 9 and 10.

The second insulating layer INS2 (or insulating pattern) may be disposed on the light emitting element LD. The second insulating layer INS2 may cover one portion of the light emitting element LD. The second insulating layer INS2 may include an organic material. However, the present disclosure is not limited thereto, and the second insulating layer INS2 may include an inorganic material. At least a portion of the second insulating layer INS2 may fill a gap (or cavity) formed at the bottom of the light emitting element LD.

The first and second pixel electrodes ELT1 and ELT2 may be disposed on the first insulating layer INS1 and the second insulating layer INS2. The first pixel electrode ELT1 may electrically connect the first alignment electrode ALE1 and the light emitting element LD to each other, and the second pixel electrode ELT2 may electrically connect the second alignment electrode ALE2 and the light emitting element LD to each other.

The first pixel electrode ELT1 may provide the anode signal to the light emitting element LD, and the second pixel electrode ELT2 may provide the cathode signal to the light emitting element LD.

The first and second pixel electrodes ELT1 and ELT2 may include a conductive material. In an example, the first and second pixel electrodes ELT1 and ELT2 may be formed through the same process, and include the same material. For example, the first and second pixel electrodes ELT1 and ELT2 may include a transparent conductive material including Indium Tin Oxide (ITO), Indium Zinc Oxide (IZO), and/or Indium Tin Zinc Oxide (ITZO), but the present disclosure is not limited thereto.

The third insulating layer INS3 may be disposed over the first and second pixel electrodes ELT1 and ELT2 and the second insulating layer INS2, to protect components of the display element layer DPL from external influence (e.g., moisture and the like). For example, the third insulating layer INS3 may include at least one of silicon nitride (SiNₓ), silicon oxide (SiOₓ), silicon oxynitride (SiOₓN_{y}), or aluminum oxide (AlOₓ).

The structure of the sub-pixel SPXL is not limited to the example described above with reference to FIG. 6, and various modifiable embodiments may be implemented.

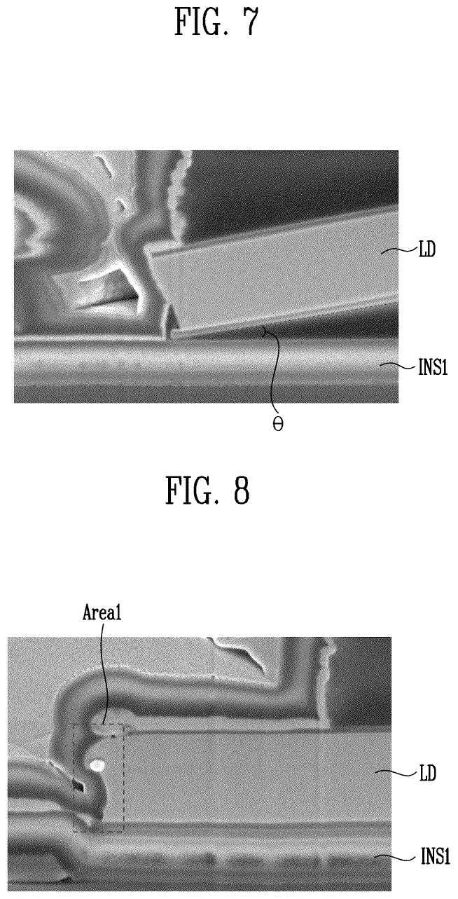

FIGS. 7 and 8 are sectional views illustrating an example of the light emitting element disposed in the display device shown in FIG. 3.

FIG. 7 is a view illustrating a state in which the light emitting element LD is disposed inclined obliquely on the first insulating layer INS1.

Referring to FIGS. 5 to 7, ink including light emitting elements LD may be provided in a space in which a fluid can be accommodated in a manufacturing process of the display device. The light emitting element LD may be obliquely disposed on the first insulating layer INS1 by a gap (or step difference) formed between the first and second alignment electrodes ALE1 and ALE2. The light emitting element LD may form an angle (e.g., a predetermined angle) 6 with the first insulating layer INS1.

In a state in which the light emitting element LD is disposed to be inclined, the first pixel electrode ELT1 and/or the second pixel electrode ELT2 may not be normally deposited on the light emitting element LD. Therefore, when the first and second pixel electrodes ELT1 and ELT2 are electrically connected to the light emitting element LD, a contact failure may be caused between the light emitting element LD and the first and second pixel electrodes ELT1 and ELT2. When the contact failure is caused between the light emitting element LD and the first and second pixel electrodes ELT1 and ELT2, the light emitting element LD corresponds to a failure state (e.g., a non-lighting state), and therefore, the light emission efficiency of the display device may be deteriorated.

FIG. 8 is a view illustrating a fracture surface of the light emitting element LD disposed on a plane of the first insulating layer INS1.

Referring to FIGS. 1, 2, and 8, ink including light emitting elements LD may be provided in a space in which a fluid can be accommodated in a manufacturing process of the display device. The light emitting element LD may be stably mounted on the first insulating layer INS1. However, referring to a first area Areal, a fracture surface of the light emitting element LD, which forms a first end portion EP1 and/or a second end portion EP2 of the light emitting element LD, may be in a failure state. For example, in a state in which an unevenness is formed at the fracture surface of the light emitting element LD or a state in which a portion of an insulative film INF adjacent to the first end portion EP1 and/or the second end portion EP2 is removed, the fracture surface of the light emitting element LD may be in the failure state.

In the state in which the fracture surface of the light emitting element LD is faulty, a contact failure (or an increase in contact resistance) may be caused between the light emitting element LD and the first and second pixel electrodes ELT1 and ELT2 when the first and second pixel electrodes ELT1 and ELT2 are electrically connected to the light emitting element LD through the first and second end portions EP1 and EP2. When the contact failure is caused between the light emitting element LD and the first and second pixel electrodes ELT1 and ELT2, the light emitting element LD corresponds to a failure state (e.g., a non-lighting state), and therefore, the light emission efficiency of the display device may be deteriorated.

FIG. 9 is an enlarged view illustrating an embodiment of an area A shown in FIG. 6.

FIG. 9 illustrates a light emitting element LD disposed in the forward direction between the first and second alignment electrodes ALE1 and ALE2. The light emitting element LD shown in FIG. 9 may correspond to the light emitting element LD shown in FIG. 3. The light emitting element LD may be connected in the forward direction between the first pixel electrode ELT1 and the second pixel electrode ELT2 to constitute an effective light source. A first semiconductor SEC1 of the light emitting element LD may be electrically connected to the first pixel electrode ELT1 (via the electrode layer EL), and a second semiconductor layer SEC2a of the light emitting element LD may be electrically connected to the second pixel electrode ELT2.

An electrode layer EL, the first semiconductor layer SEC1, an active layer AL, the second semiconductor layer SEC2a, a third semiconductor layer SEC3, and a fourth semiconductor layer SEC2b may be sequentially disposed in the first direction DR1 in the light emitting element LD.

An insulative film INF may include a first insulative film INF1, a second insulating layer INF2, and an opening OP1 formed between the first insulative film INF1 and the second insulative film INF2.

The first insulative film INF1 may cover outer surfaces (e.g., outer peripheral or circumferential surfaces) of the first semiconductor layer SEC1, the active layer AL, and a portion of the second semiconductor layer SEC2a. The first insulative film INF1 may completely cover the outer surfaces (e.g., the outer peripheral or circumferential surfaces) of the first semiconductor layer SEC1 and the active layer AL. The second semiconductor layer SEC2a surrounded by the first insulative film INF1 may be a portion corresponding to an area overlapping with the second insulating layer INS2 and the first pixel electrode ELT1.

The second insulative film INF2 may cover outer surfaces (e.g., outer peripheral or circumferential surfaces) of a portion of the second semiconductor layer SEC2a, the third semiconductor layer SEC3, and the fourth semiconductor layer SEC2b. The second insulative film INF2 may completely cover the outer surfaces (e.g., the outer peripheral or circumferential surfaces) of the third semiconductor layer SEC3 and the fourth semiconductor layer SEC2b. In FIG. 9, it is illustrated that the second semiconductor layer SEC2a adjacent to the opening OP1 is covered by the second insulating layer INS2. However, the second semiconductor layer SEC2a may not be covered by the second insulative film INF2.

The first insulative film INF1 and the second insulative film INF2 may be disposed while being spaced from each other with the opening OP1 interposed therebetween. In an example, the first and second insulative films INF1 and INF2 may have a structure in which the first and second insulative films INF1 and INF2 are completely separated from each other by the opening OP1.

A length of the first insulative film INF1 in the first direction DR1 may be longer than a length of the second insulative film INF2 in the first direction DR1. That is, an area covered through the first insulative film INF1 may be wider than an area covered through the second insulative film INF2.

The opening OP1 may be disposed at a side surface portion of the light emitting element LD. The side surface portion of the light emitting element LD may refer to a surface of the light emitting element LD except first and second end portions EP1 and EP2 of the light emitting element LD. In an example, the opening OP1 may be disposed to face in the display direction (e.g., the third direction DR3). The insulative film INF may partially expose the second semiconductor layer SEC2a through the opening OP1. One area of the outer surface (e.g., the outer peripheral or circumferential surface) of the second semiconductor layer SEC2a may be exposed by the opening OP1. The outer surface (e.g., the outer peripheral or circumferential surface) of the second semiconductor layer SEC2a may include an area except a first surface in contact with the active layer AL and a second surface in contact with the third semiconductor layer SEC3.

The second pixel electrode ELT2 may be disposed on the opening OP1. The opening OP1 may overlap with the second semiconductor layer SEC2a when viewed on a plane (e.g., in a plan view) or in third direction DR3.

The second pixel electrode ELT2 may be in contact with the second semiconductor layer SEC2a through the opening OP1. When viewed on a plane (e.g., in a plan view), the opening OP1 may overlap with the second pixel electrode ELT2, and may not overlap with the first pixel electrode ELT1 and the second insulating layer INS2.

The opening OP1 may be disposed while being spaced from the active layer AL at a first distance. The opening OP1 may be disposed while being spaced from the third semiconductor layer SEC3 at a second distance. The first distance may be longer than the second distance. That is, the opening OP1 may be formed more adjacent to the third semiconductor layer SEC3 than the active layer AL.

A first power voltage (e.g., an anode signal) may be applied to the first pixel electrode ELT1 to be transferred to the first end portion EP1, and a second power voltage (e.g., a cathode signal) may be applied to the second pixel electrode ELT2 to be transferred to the opening OP1 and the second end portion EP2. A current may flow through the light emitting element LD by the first power voltage and the second power voltage.

The third semiconductor layer SEC3 may prevent a current applied through the fourth semiconductor layer SEC2b as the second end portion EP2 of the light emitting element LD from flowing into the second semiconductor layer SEC2a. The third semiconductor layer SEC3 may include a material having a band gap energy higher than a band gap energy of each of the second semiconductor layer SEC2a and the fourth semiconductor layer SEC2b. Electrons injected into the third semiconductor layer SEC3 can be prevented from flowing into the second semiconductor layer SEC2a and/or the fourth semiconductor layer SEC2b. That is, no current can flow through the third semiconductor layer SEC3.

The light emitting element LD may provide light, based on the anode signal provided from the first pixel electrode ELT1 through the first end portion EP1 and the cathode signal provided from the second pixel electrode ELT2 through the opening OP1.

The cathode signal may be applied to the light emitting element LD from the second pixel electrode ELT2 through the opening OP1, regardless of the shape the second end portion EP2 (e.g., the shape of a fracture surface) of the light emitting element LD. Thus, a contact resistance between the light emitting element LD and the pixel electrodes ELT1 and ELT2, which is caused by the shape of the fracture surface of the light emitting element LD, can be reduced (or minimized). In addition, deterioration of light emission efficiency according to an alignment state of the light emitting element LD aligned between the first and second alignment electrodes ALE1 and ALE2 when viewed on a plane (e.g., in a plan view) can be reduced (or minimized).

FIG. 10 is an enlarged view illustrating an embodiment of the area A shown in FIG. 6.

FIG. 10 illustrates a light emitting element LD disposed in the reverse direction between the first and second alignment electrodes ALE1 and ALE2. The light emitting element LD shown in FIG. 10 may correspond to the reverse light emitting element LDr shown in FIG. 4. The light emitting element LD may be connected in the reverse direction between the first pixel electrode ELT1 and the second pixel electrode ELT2 to constitute a non-effective light source. That is, a fourth semiconductor layer SEC2b of the light emitting element LD may be electrically connected to the first pixel electrode ELT1, and a first semiconductor layer SEC1 of the light emitting element LD may be electrically connected to the second pixel electrode ELT2 (e.g., via the electrode layer EL).

The fourth semiconductor layer SEC2b, a third semiconductor layer SEC3, a second semiconductor layer SEC2a, an active layer AL, the first semiconductor layer SEC1, and an electrode layer EL may be sequentially disposed in the light emitting element LD.

An insulative film INF may include a first insulative film INF1′, a second insulative film INF2′, and an opening OP1′ formed between the first insulative film INF1′ and the second insulative film INF2′.

The first insulative film INF1′ may cover outer surfaces (e.g., outer peripheral or circumferential surfaces) of the first semiconductor layer SEC1, the active layer AL, and a portion of the second semiconductor layer SEC2a. The first insulative film INF1′ may completely cover the outer surfaces (e.g., outer peripheral or circumferential surfaces) of the first semiconductor layer SEC1 and the active layer AL. The second semiconductor layer SEC2a surrounded by the first insulative film INF1′ may be a portion corresponding to an area overlapping with the second pixel electrode ELT2. In FIG. 10, it is illustrated that the second semiconductor layer SEC2a adjacent to the opening OP1′ is covered by the first insulative film INF1′. However, the second semiconductor layer SEC2a may not be covered by the first insulative film INF1′.

The second insulative film INF2′ may cover outer surfaces (e.g., outer peripheral or circumferential surfaces) of a portion of the second semiconductor layer SEC2a, the third semiconductor layer SEC3, and the fourth semiconductor layer SEC2b. The second insulative film INF2′ may completely cover the outer surfaces (e.g., the outer peripheral or circumferential surfaces) of the third semiconductor layer SEC3 and the fourth semiconductor layer SEC2b. The second semiconductor layer SEC2a surrounded by the second insulative film INF2′ may be a portion corresponding to an area overlapping with the second insulating layer INS2 and the first pixel electrode ELT1.

The first insulative film INF1′ and the second insulative film INF2′ may be disposed while being spaced from each other with the opening OP1′ interposed therebetween. In an example, the first and second insulative films INF1′ and INF2 may have a structure in which the first and second insulative films INF1′ and INF2 are completely separated from each other by the opening OP1′.

A length of the second insulative film INF2′ in the first direction DR1 may be longer than a length of the first insulative film INF1′ in the first direction DR1. That is, an area covered through the second insulative film INF2′ may be wider than an area covered through the first insulative film INF1′.

The opening OP1′ may be disposed at a side surface portion of the light emitting element LD. The opening OP1′ may be disposed to face in the display direction (e.g., the third direction DR3). The insulative film INF may expose one side surface of the second semiconductor layer SEC2a through the opening OP1′. The second pixel electrode ELT2 may be disposed on the opening OP1′. The opening OP1′ may overlap with the second semiconductor layer SEC2a when viewed on a plane (e.g., in a plan view). The second pixel electrode ELT2 may be in contact with the second semiconductor layer SEC2a through the opening OP1′. When viewed on a plane (e.g., in a plan view), the opening OP1′ may overlap with the second pixel electrode ELT2, and may not overlap with the first pixel electrode ELT1 and the second insulating layer INS2.

The opening OP1′ may be disposed while being spaced from the active layer AL at a first distance. The opening OP1′ may be disposed while being spaced from the third semiconductor layer SEC3 at a second distance. The second distance may be longer than the first distance. That is, the opening OP1′ may be formed more adjacent to the active layer AL than the third semiconductor layer SEC3.

The light emitting element LD may become a non-effective light source in a state in which the light emitting element LD is connected in the reverse direction between the first pixel electrode ELT1 and the second pixel electrode ELT2 (non-light emission). A cathode signal may be applied from the second pixel electrode ELT2 through a first end portion EP1 of the light emitting element LD and the opening OP1′. Although the second pixel electrode ELT2 is in contact with the first semiconductor layer SEC1 and the second semiconductor layer SEC2a, a current can be blocked from being moved to a second end portion EP2 of the light emitting element LD by the third semiconductor layer SEC3, and thus occurrence of an electrical short-circuit phenomenon can be prevented.

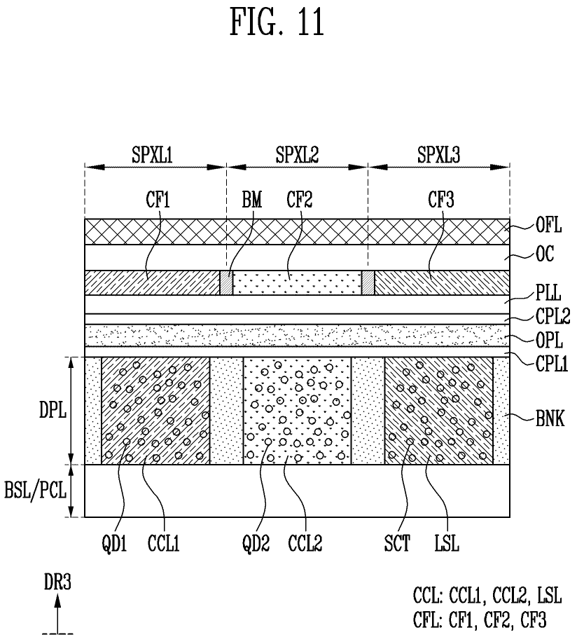

FIG. 11 is a sectional view illustrating the pixel included in the display device shown in FIG. 3.

FIG. 11 illustrates the bank BNK, a color conversion layer CCL, an optical layer OPL, and/or a color filter layer CFL, which are provided on the pixel circuit layer PCL of the sub-pixel SPXL. In FIG. 11, the components of the pixel circuit layer PCL and the components except the bank BNK of the display element layer DPL from among the above-described components are omitted.

FIG. 11 may illustrate a stacked structure of the pixel PXL in relation to the color conversion layer CCL, the optical layer OPL, and the color filter layer CFL.

Referring to FIGS. 10 and 11, the bank BNK may be disposed between first to third pixels PXL1, PXL2, and PXL3 or at a boundary of the first to third pixels PXL1, PXL2, and PXL3, and include a space (or area) overlapping with each of the first to third pixels PXL1, PXL2, and PXL3. The space defined by the bank BNK may be an area in which the color conversion layer CCL can be provided.

The color conversion layer CCL may be disposed over light emitting elements LD in the space surrounded by the bank BNK. The color conversion layer CCL may include a first color conversion layer CCL1 disposed in the first pixel PXL1, a second color conversion layer CCL2 disposed in the second pixel PXL2, and a light scattering layer LSL disposed in the third pixel PXL3.

The color conversion layer CCL may be disposed over the light emitting element LD. The color conversion layer CCL may be configured to change a wavelength of light. In one or more embodiments, the first to third pixels PXL1, PXL2, and PXL3 may include light emitting elements LD emitting light of the same color. For example, the first to third pixels PXL1, PXL2, and PXL3 may include light emitting elements LD emitting light of a third color (or blue). The color conversion layer CCL including color conversion particles is disposed on each of the first to third pixels PXL1, PXL2, and PXL3, so that a full-color image can be displayed.

The first color conversion layer CCL1 may include first color conversion particles for converting light of the third color, which is emitted from the light emitting element LD, into light of a first color. For example, the first color conversion layer CCL1 may include a plurality of first quantum dots QD1 dispersed in a suitable matrix material (e.g., a predetermined matrix material) such as base resin.

When the light emitting element LD is a blue light emitting element emitting light of blue color, and the first sub-pixel SPXL1 is a red pixel, the first color conversion layer CCL1 may include a first quantum dot QD1 for converting light of blue color, which is emitted from the blue light emitting element, into light of red color. The first quantum dot QD1 may absorb blue light and emit red light by shifting a wavelength of the blue light according to energy transition. In one or more embodiments, when the first sub-pixel SPXL1 is a pixel of another color, the first color conversion layer CCL1 may include a first quantum dot QD1 corresponding to the color of the first sub-pixel SPXL1.

The second color conversion layer CCL2 may include second color conversion particles for converting light of the third color, which is emitted from the light emitting element LD, into light of a second color. For example, the second color conversion layer CCL2 may include a plurality of second quantum dots QD2 dispersed in a suitable matrix material (e.g., a predetermined matrix material) such as a base resin.

When the light emitting element LD is a blue light emitting element emitting light of blue, and the second sub-pixel SPXL2 is a green pixel, the second color conversion layer CCL2 may include a second quantum dot QD2 for converting light of blue color, which is emitted from the blue light emitting element, into light of green color. The second quantum dot QD2 may absorb blue light and emit green light by shifting a wavelength of the blue light according to energy transition. In one or more embodiments, when the second sub-pixel SPXL2 is a pixel of another color, the second color conversion layer CCL2 may include a second quantum dot QD2 corresponding to the color of the second sub-pixel SPXL2.

Light of blue color having a relatively short wavelength in a visible light band is incident into the first quantum dot QD1 and the second quantum dot QD2, so that absorption coefficients of the first quantum dot QD1 and the second quantum dot QD2 can be increased. Accordingly, the efficiency of light finally emitted from the first sub-pixel SPXL1 and the second sub-pixel SPXL2 can be improved, and excellent color reproduction can be ensured. In addition, the light emitting unit EMU of each of the first to third sub-pixels SPXL1, SPXL2, and SPXL3 is configured by using light emitting elements of the same color (e.g., blue light emitting elements), so that the manufacturing efficiency of the display device DD can be improved.

The light scattering layer LSL may be provided to efficiently use light of the third color (or blue) emitted from the light emitting element LD. In an example, when the light emitting element LD is a blue light emitting element emitting light of blue color, and the third sub-pixel SPXL3 is a blue pixel, the light scattering layer LSL may include at least one kind (or type) of light scattering particle SCT to efficiently use light emitted from the light emitting element LD. In an example, the light scattering particle SCT of the light scattering layer LSL may include at least one of titanium oxide (TiO₂), barium sulfate (BaSO₄), calcium carbonate (CaCO₃), silicon oxide (SiO₂), silicon nitride (Si₃N₄), aluminum oxide (Al₂O₃), zirconium oxide (ZrO₂), or zinc oxide (ZnO). In one or more embodiments, the light scattering particle SCT is not disposed only in the third sub-pixel SPXL3, and may be selectively included in the first color conversion layer CCL1 or the second color conversion layer CCL2. In one or more embodiments, the light scattering particle SCT may be omitted such that the light scattering layer LSL configured with transparent polymer is provided.

A first capping layer CPL1 may be disposed on the color conversion layer CCL. The first capping layer CPL1 may be provided through the first to third sub-pixels SPXL1, SPXL2, and SPXL3. The first capping layer CPL1 may cover the color conversion layer CCL. The first capping layer CPL1 may prevent the color conversion layer CCL from being damaged or contaminated due to infiltration of an impurity such as moisture or air from the outside.

The first capping layer CPL1 is an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), and/or the like.

The optical layer OPL may be disposed on the first capping layer CPL. The optical layer OPL may function to improve light extraction efficiency by recycling light provided from the color conversion layer CCL through total reflection. To this end, the optical layer OPL may have a refractive index relatively lower than a refractive index of the color conversion layer CCL. For example, the refractive index of the color conversion layer may be about 1.6 to about 2.0, and the refractive index of the optical layer OPL may be about 1.1 to about 1.3.

A second capping layer CPL2 may be disposed on the optical layer OPL. The second capping layer CPL2 may be provided throughout the first to third sub-pixels SPXL1, SPXL2, and SPXL3. The second capping layer CPL2 may cover the optical layer OPL. The second capping layer CPL2 may prevent the optical layer OPL from being damaged or contaminated due to infiltration of an impurity such as moisture or air from the outside.

The second capping layer CPL2 is an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), and/or the like.

A planarization layer PLL may be disposed on the second capping layer CPL2. The planarization layer PLL may be provided throughout the first to third sub-pixels SPXL1, SPXL2, and SPXL3.

The planarization layer PLL may include an organic material such as acrylic resin, epoxy resin, phenolic resin, polyamide resin, polyimide resin, unsaturated polyester resin, poly-phenylene ether resin, poly-phenylene sulfide resin, and/or benzocyclobutene (BCB). However, the present disclosure is not necessarily limited thereto, and the planarization layer PLL may include various kinds (or types) of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CFL may be disposed on the planarization layer PLL. The color filter layer CFL may include color filters CF1, CF2, and CF3 corresponding to a color of each pixel PXL. The color filters CF1, CF2, and CF3 which correspond to a color of each of the first to third sub-pixels SPXL1, SPXL2, and SPXL3 are disposed, so that a full-color image can be displayed.

The color filter layer CFL may include a first color filter CF1 disposed in the first sub-pixel SPXL1 to allow light emitted from the first sub-pixel SPXL1 to be selectively transmitted therethrough, a second color filter CF2 disposed in the second sub-pixel SPXL2 to allow light emitted from the second sub-pixel SPXL2 to be selectively transmitted therethrough, and a third color filter CF3 disposed in the third sub-pixel SPXL3 to allow light emitted from the third sub-pixel SPXL3 to be selectively transmitted therethrough.

In one or more embodiments, the first color filter CF1, the second color filter CF2, and the third color filter CF3 may be respectively a red color filter, a green color filter, and a blue color filter, but the present disclosure is not necessarily limited thereto. Hereinafter, when an arbitrary color filter from among the first color filter CF1, the second color filter CF2, and the third color filter CF3 is designated or when two or more kinds (or types) of color filters are inclusively designated, the corresponding color filter or the corresponding color filters are referred to as a “color filter CF” or “color filters CF.”

The first color filter CF1 may overlap with the first color conversion layer CCL1 in a thickness direction of the substrate SUB (e.g., the third direction DR3). The first color filter CF1 may include a color filter material for allowing light of a first color (or red) to be selectively transmitted therethrough. For example, when the first sub-pixel SPXL1 is a red pixel, the first color filter CF1 may include a red color filter material.

The second color filter CF2 may overlap with the second color conversion layer CCL2 in the thickness direction of the substrate SUB (e.g., the third direction DR3). The second color filter CF2 may include a color filter material for allowing light of a second color (or green) to be selectively transmitted therethrough. For example, when the second sub-pixel SPXL2 is a green pixel, the second color filter CF2 may include a green color filter material.

The third color filter CF3 may overlap with the light scattering layer LSL in the thickness direction of the substrate SUB (e.g., the third direction DR3). The third color filter CF3 may include a color filter material for allowing light of a third color (or blue) to be selectively transmitted therethrough. For example, when the third sub-pixel SPXL3 is a blue pixel, the third color filter CF3 may include a blue color filter material.

A light blocking layer BM may be disposed between the first to third color filters CF1, CF2, and CF3. When the light blocking layer BM is formed between the first to third color filters CF1, CF2, and CF3 as described above, a color mixture defect viewed at the front or side of the display device DD can be prevented. The material of the light blocking layer BM is not particularly limited, and the light blocking layer BM may be configured with various light blocking materials. In an example, the light blocking layer BM may include a black matrix, or be implemented as the first to third color filters CF1, CF2, and CF3 are stacked with each other.

An overcoat layer OC may be disposed on the color filter layer CFL. The overcoat layer OC may be provided throughout the first to third sub-pixels SPXL1, SPXL2, and SPXL3. The overcoat layer OC may cover a lower member including the color filter layer CFL. The overcoat layer OC may prevent moisture or air from infiltrating into the above-described lower member. Also, the overcoat layer OC may protect the above-described lower member from a foreign matter such as dust.

The overcoat layer OC may include an organic material such as acrylic resin, epoxy resin, phenolic resin, polyamide resin, polyimide resin, unsaturated polyester resin, poly-phenylene ether resin, poly-phenylene sulfide resin, and/or benzocyclobutene (BCB). However, the present disclosure is not necessarily limited thereto, and the overcoat layer OC may include an inorganic material.

An outer film layer OFL may be disposed on the overcoat layer OC. The outer film layer OFL may be disposed at an outer portion of the display device DD, to reduce external influence. The outer film layer OFL may be provided throughout the first to third sub-pixels SPXL1, SPXL2, and SPXL3. In one or more embodiments, the outer film layer OFL may include one of a polyethylenephthalate (PET) film, a low reflective film, a polarizing film, and/or a transmittance controllable film, but the present disclosure is not necessarily limited thereto. In one or more embodiments, the pixel PXL may include an upper substrate instead of the outer film layer OFL.

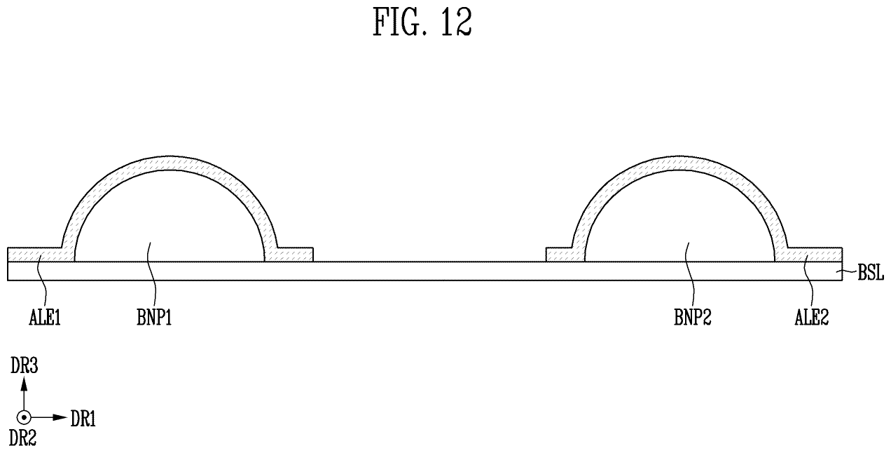

FIGS. 12 to 17 are schematic sectional views illustrating a method of manufacturing the display device in accordance with one or more embodiments of the present disclosure.

Hereinafter, a method of manufacturing the display element layer DPL of the sub-pixel SPXL shown in FIG. 9 will be sequentially described with reference to FIGS. 12 to 17.

In this specification, although it is described that manufacturing steps of the sub-pixels SPXL are sequentially performed according to the sectional views, without changing the spirit of the present disclosure, some steps illustrated as being successively performed may be simultaneously performed, the sequence of the steps may be changed, some steps may be omitted, or another step may be further included between the steps.

In FIGS. 12 to 17, portions different from those of the above-described embodiment will be mainly described to avoid redundancy.

Referring to FIG. 12, first and second bank patterns BNP1 and BNP2 may be formed on a base substrate BSL. A first alignment electrode ALE1 may be formed over the first bank pattern BNP1, and a second alignment electrode ALE2 may be formed over the second bank pattern BNP2.

The base substrate BSL may constitute a base member of the display device DD. The base substrate BSL may be a rigid or flexible substrate or film. For example, the base substrate BSL may be a rigid substrate made of glass or tempered glass, a flexible substrate (or thin film) made of a plastic or metal material, or at least one insulating layer. The material and/or property of the base substrate BSL is not particularly limited. In one or more embodiments, the base substrate BSL may be substantially transparent. The term “substantially transparent” may mean that light can be transmitted with a suitable transmittance (e.g., a predetermined transmittance) or more. In another embodiment, the base substrate BSL may be translucent or opaque. Also, the base substrate BSL may include a reflective material in some embodiments. In an example, the base substrate BSL may be one component constituting the pixel circuit layer PCL shown in FIG. 6.

The first bank pattern BNP1 and the second bank pattern BNP2 may be formed while being spaced from each other in the first direction DR1. The first bank pattern BNP1 may be formed to overlap with the first alignment electrode ALE1. The second bank pattern BNP2 may be formed to overlap with the second alignment electrode ALE2.

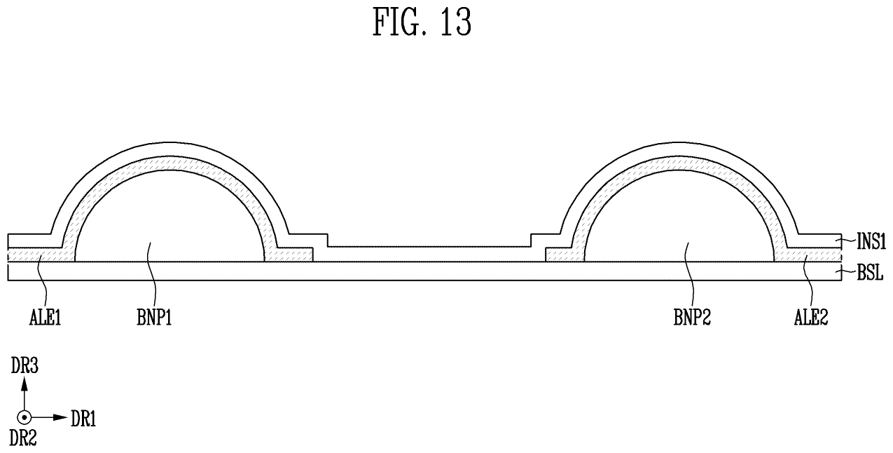

Referring to FIG. 13, a first insulating layer INS1 may be formed to cover the base substrate BSL, the first and second bank patterns BNP1 and BNP2, and the first and second alignment electrodes ALE1 and ALE2.

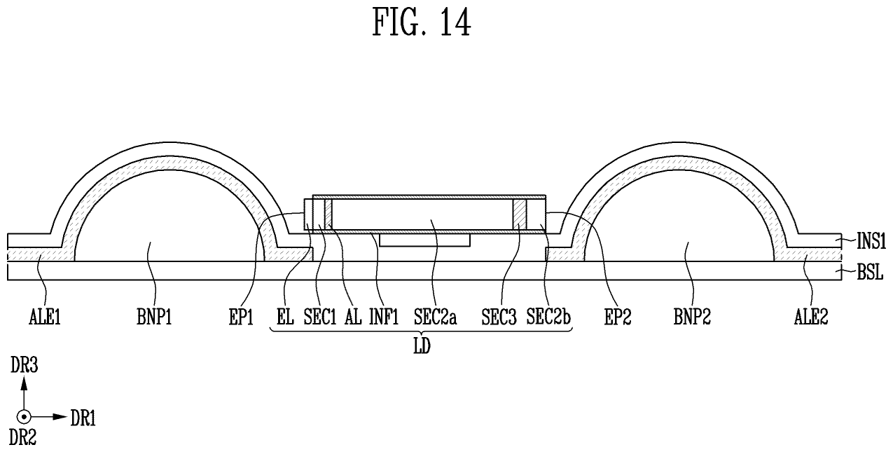

Referring to FIG. 14, a light emitting element LD may be provided on the first insulating layer INS1 between the first and second alignment electrodes ALE1 and ALE2. The light emitting element LD may be dispersed in a solvent having fluidity to be sprayed onto the first insulating layer INS1 through ink. The light emitting element LD may be arranged between the first and second alignment electrodes ALE1 and ALE2.

The light emitting element LD may be moved to an area in which the light emitting element LD is to be disposed by a dielectrophoresis (DEP) generated based on an electrical signal provided to the first and second alignment electrodes ALE1 and ALE2.

In this step, the electrical signal is provided to the first and second alignment electrodes ALE1 and ALE2, so that an electric field can be formed between the first and second alignment electrodes ALE1 and ALE2.

A first electrical signal may be provided to the first alignment electrode ALE1, and a second electrical signal may be provided to the second alignment electrode ALE2. In addition, the light emitting element LD may be arranged based on an electric field according to the first electrical signal and the second electrical signal. In an example, each of the first electrical signal and the second electrical signal may be any one of a sine wave, a triangular wave, a stepped wave, a square wave, a trapezoidal wave, and a pulse wave. However, the present disclosure is not limited to a specific example.

The light emitting element LD may be aligned in a forward direction between the first and second alignment electrodes ALE1 and ALE2.

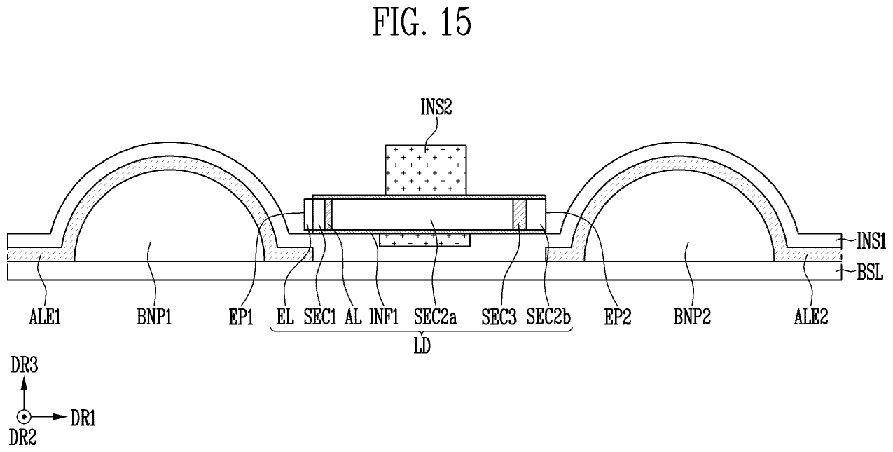

Referring to FIG. 15, a second insulating layer INS2 may be formed on the light emitting element LD. The second insulating layer INS2 may be formed to overlap with a second semiconductor layer SEC2a of the light emitting element LD.

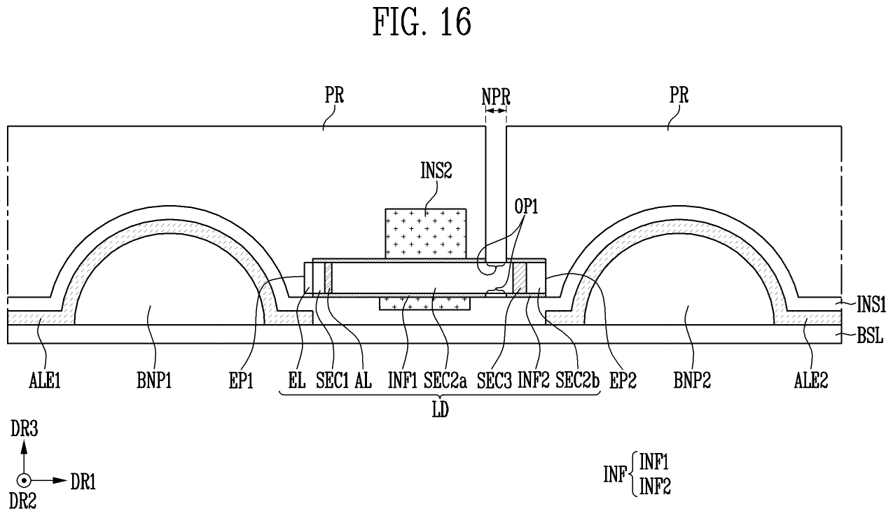

Referring to FIG. 16, an opening OP1 may be formed by removing a portion of an insulative film INF. The opening OP1 may be one area corresponding to the second semiconductor layer SEC2a overlapping with a second pixel electrode ELT2 disposed according to a subsequent process.

A photoresist pattern PR may be formed in the other area except an area in which the insulative film INF is to be removed, and no photoresist pattern is formed in the area in which the insulative film INF is to be removed (i.e., an area NPR in which the photoresist pattern PR is not disposed). Components disposed in the other area except the area in which the insulative film INF is to be removed may maintain their shapes through the photoresist pattern PR. The area in which the insulative film INF is to be removed may be removed through a photolithography process.

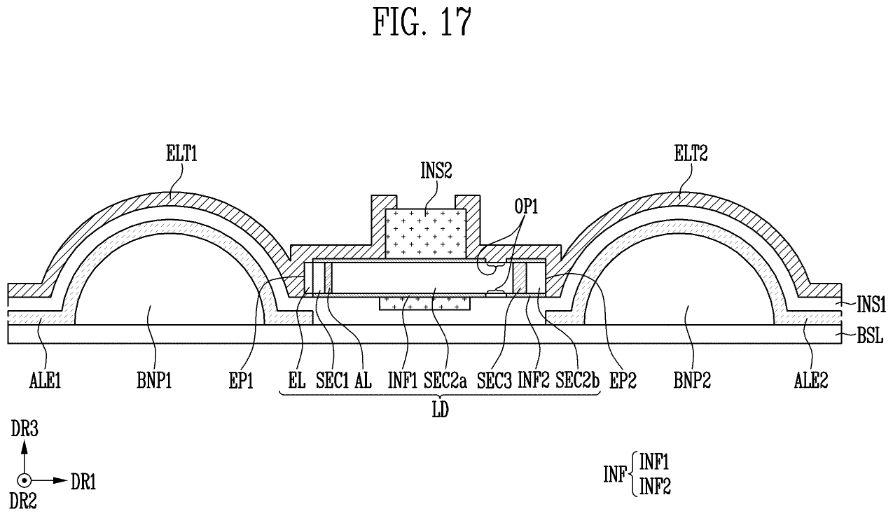

Referring to FIG. 17, a first pixel electrode ELT1 and the second pixel electrode ELT2 may be formed on the first insulating layer INS1, the light emitting element LD, and the second insulating layer INS2.

The first and second pixel electrodes ELT1 and ELT2 may be disposed according to a profile (or shape) of the first and second bank patterns BNP1 and BNP2, the first insulating layer INS1, and the second insulating layer INS2.

The first pixel electrode ELT1 may be connected to a first end portion (e.g., a first semiconductor layer SEC1 (e.g., via the electrode layer EL)) of the light emitting element LD. The second pixel electrode ELT2 may be connected to the second semiconductor layer SEC2a through the opening OP1 of the light emitting element LD.

In the display device and the method of manufacturing the same in accordance with the embodiments of the present disclosure, a light emitting element and a pixel electrode are electrically connected to each other through an opening formed at a side surface portion of the light emitting element, so that a contact resistance between the light emitting element and the pixel electrode, which is caused by the shape of a fracture surface of the light emitting element, can be reduced (or minimized).

In addition, as another semiconductor layer for blocking electrical flow between semiconductor layers is included, an electrical short-circuit phenomenon can be prevented, which may occur when the alignment direction of the light emitting element is a reverse direction (e.g., a non-light emission state of the light emitting element).

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a substrate;
a light emitting element on the substrate;
a first pixel electrode on one area of the light emitting element, the first pixel electrode being electrically connected to the light emitting element; and
a second pixel electrode on an other area of the light emitting element, the second pixel electrode being electrically connected to the light emitting element,
wherein the light emitting element comprises:
a first semiconductor layer, an active layer, a second semiconductor layer, and a third semiconductor layer sequentially arranged along a first direction; and
an insulative film covering outer surfaces of the first semiconductor layer, the active layer, the second semiconductor layer, and the third semiconductor layer,
wherein an opening exposes at least one side surface of the second semiconductor layer to the outside while penetrating the insulative film, and
wherein the second pixel electrode is in contact with the second semiconductor layer.

2. The display device of claim 1, wherein, in a plan view, the opening of the insulative film does not overlap with the active layer and the third semiconductor layer.

3. The display device of claim 2, wherein the opening of the insulative film is closer to the third semiconductor layer than to the active layer.

4. The display device of claim 2, wherein the opening of the insulative film is closer to the active layer than to the third semiconductor layer.

5. The display device of claim 2, wherein the first semiconductor layer is a semiconductor layer doped with a p-type dopant,
the second semiconductor layer is a semiconductor layer doped with an n-type dopant, and
the third semiconductor layer is a semiconductor layer that is not doped.

6. The display device of claim 5, wherein the light emitting element comprises a first end portion and a second end portion opposite the first end portion,
wherein the first semiconductor layer of the light emitting element is adjacent to the first end portion, and the third semiconductor layer of the light emitting element is adjacent to the second end portion, and
wherein the light emitting element further comprises a fourth semiconductor layer arranged on the third semiconductor layer in the first direction, the fourth semiconductor layer being in contact with the second end portion.

7. The display device of claim 6, wherein the fourth semiconductor layer is a semiconductor layer doped with an n-type dopant.

8. The display device of claim 6, wherein the insulative film comprises:
a first insulative film surrounding outer surfaces of one area of the second semiconductor layer, the first semiconductor layer, and the active layer; and
a second insulative film surrounding outer surfaces of an other area of the second semiconductor layer, the third semiconductor layer, and the fourth semiconductor layer, and
wherein the opening is between the first insulative film and the second insulative film.

9. The display device of claim 8, wherein the first pixel electrode is electrically connected to the first semiconductor layer while being in contact with the first end portion of the light emitting element, and
wherein the second pixel electrode is electrically connected to the second semiconductor layer while being in contact with the second semiconductor layer exposed through the opening.

10. The display device of claim 9, wherein the third semiconductor layer comprises at least one of AlGaInN, GaN, AlGaN, InGaN, AlN, or InN, and
wherein the second pixel electrode is in contact with the fourth semiconductor layer through the second end portion of the light emitting element.

11. The display device of claim 9, wherein the first pixel electrode is an anode electrode, and
the second pixel electrode is a cathode electrode.

12. The display device of claim 1, wherein, in a cross sectional view, the light emitting element is inclined with respect to the substrate.

13. The display device of claim 1, further comprising an insulating pattern on the light emitting element,
wherein, in a plan view, the first pixel electrode and the second pixel electrode respectively cover both ends of the insulating pattern, and
wherein the insulating pattern comprises an organic material.

14. The display device of claim 13, wherein, in a plan view, the opening of the insulative film does not overlap with the insulating pattern.

15. The display device of claim 13, wherein, in a plan view, the first pixel electrode and the insulating pattern overlap with a portion of the second semiconductor layer of the light emitting element.

16. A method of manufacturing a display device, the method comprising:
forming, on a substrate, a first alignment electrode and a second alignment electrode that are spaced from each other;
forming a first insulating layer over the first alignment electrode and the second alignment electrode;
aligning a light emitting element on the first insulating layer between the first alignment electrode and the second alignment electrode by forming an electric field between the first alignment electrode and the second alignment electrode;
forming an insulating pattern on one area of the light emitting element;
forming an opening in an insulative film of the light emitting element by etching a portion of an outer surface of the light emitting element adjacent to a second pixel electrode; and
forming a first pixel electrode in contact with a first end portion of the light emitting element and the second pixel electrode in contact with a second end portion of the light emitting element.

17. The method of claim 16, wherein the second pixel electrode is in contact with a second semiconductor layer of the light emitting element.

18. The method of claim 17, wherein the light emitting element comprises a first semiconductor layer, an active layer, the second semiconductor layer, and a third semiconductor layer sequentially arranged along a first direction,
wherein the insulative film covers outer surfaces of the first semiconductor layer, the active layer, the second semiconductor layer, and the third semiconductor layer,
wherein the first semiconductor layer is a semiconductor layer doped with a p-type dopant,
wherein the second semiconductor layer is a semiconductor layer doped with an n-type dopant, and
wherein the third semiconductor layer is a semiconductor layer that is not doped, and
wherein the forming of the opening comprises removing the insulative film surrounding at least one side surface of the second semiconductor layer.

19. The method of claim 18, wherein the light emitting element further includes a fourth semiconductor layer arranged on the third semiconductor layer in the first direction, the fourth semiconductor layer being at the second end portion,
wherein, in a plan view, the opening does not overlap with the insulating pattern, and
wherein the fourth semiconductor layer is a semiconductor layer doped with an n-type dopant.
